(19) United States
(12) Patent Application Publication
(10) Pub. No.: US 2019/0040521 A1
(43) Pub. Date: Feb. 7, 2019

(54) METHOD, COATING DEVICE AND PROCESSING ARRANGEMENT

(71) Applicant: VON ARDENNE ASSET GMBH & CO. KG, Dresden (DE)

(72) Inventor: Maik Vieluf, Moritzburg (DE)

(21) Appl. No.: 16/061,367

(22) PCT Filed: Jan. 18, 2017
(86) PCT No.: PCT/EP2017/050952

§ 371 Date: Jun. 12, 2018

(30) Foreign Application Priority Data
Jan. 21, 2016 (DE) 10 2016 101 013.8

(51) Int. Cl. C23C 14/22; C23C 14/30; B22F 1/02; H01M 4/04

(52) U.S. Cl. CPC C23C 14/223; C23C 14/30; H01M 4/131; H01M 4/0423; B22F 1/025

(57) ABSTRACT

The description relates to a method, a coating device and a processing arrangement. According to different forms of embodiment, the method may comprise the following steps: producing a vacuum in a coating region and in a collection region; emitting solid particles with a first main direction of propagation through the coating region into the collection region; and evaporating a coating material with a second main direction of propagation into the coating region, the first main direction of propagation and the second main direction of propagation extending at an angle to each other such that the coating material is evaporated past the collection region.

### CROSS-REFERENCE TO RELATED APPLICATIONS

This application is a national stage entry according to 35 U.S.C. 371 of PCT Application No. PCT/EP2017/050952 filed on Jan. 18, 2017, which claims priority to German Application No. DE 10 2016 101 013.8 filed on Jan. 21, 2016, which are entirely incorporated herein by reference.

### TECHNICAL FIELD

The description relates to a method, a coating device and a processing arrangement.

### SUMMARY

Generally, surfaces can be coated to functionalize them, for example to change their physical and/or chemical properties. In the area of batteries, layers of active material can by way of illustration be used to ensure high capacities or a great ability to intercalate ions. For example, the electrodes in lithium-ion batteries are coated with the active material that has a surface of the highest possible activity for a given layer thickness, in order to be conducive to the intercalation (insertion) of lithium ions. In the area of fuel cells, gas diffusion layers (so-called GDLs) or MPLs (microporous layers) can be provided as a coating to increase their electrical conductivity, catalytic effectiveness, the degree of fine distribution by gas permeability and/or their water repellency.

Generally, solid particles can be used to functionalize surfaces. For example, solid particles can be used as a means to achieve a surface protection which for example increases the wear resistance or chemical resistance. As an alternative, the solid particles can be used as a means for achieving a surface activation which increases the active surface and/or the chemical reactivity. For example, the solid particles can be used as a means for producing porous layers.

For applying the solid particles to a surface to be treated or coated, various methods are known, depending on the surface layer thickness to be achieved. Often, the solid particles are wet-chemically or mechanically mixed with a binder, and for example applied to the surface by spraying, slot die coating, screen printing or so-called spin coating and dried in a subsequent process. The binder-based coating (wet-chemical coating) makes a very high throughput possible with low costs, and is therefore particularly economical and suitable for large-scale industrial production. The processed solid particles may consist of the functional material themselves or themselves be a carrier for it (i.e. they may be coated with the functional material). For example, the solid particles can themselves likewise be functionalized by means of a coating, in order for example to change their physical and/or chemical properties. As an alternative or in addition, it may be necessary to coat the functional material itself, for example to chemically passivate it. The coating of the solid particles themselves should take place before the wet-chemical coating.

However, in comparison with the wet-chemical coating, the methods that are conventionally used for coating the solid particles have a much lower throughput, with greater costs. Furthermore, additional measures are needed to prevent the solid particles from sticking to one another while they are being applied as a coating and forming clusters, which can no longer be processed and therefore contaminate the material made up by the solid particles. For coating the solid particles, conventionally so-called cathode sputtering or a freefall fluidized bed granulator coating is used, methods which are in particular time-consuming. In order to compensate for this low throughput, a large number of coating installations must be provided, which increase the area taken up, procurement costs, maintenance and personnel costs.

Therefore, the coating of the solid particles represents a great cost factor, which in large-scale industrial production can exceed the limits of cost-effectiveness. For example, in large-scale industrial production, each production installation may consume several hundred kilograms of solid particles, the coating of which itself in turn may require several production installations.

According to various embodiments, a method, a coating device and a processing arrangement that by way of illustration provide a greater throughput during the coating of solid particles are provided.

By way of illustration, an electron-beam-based coating of the solid particles is provided, a way of coating which, compared to conventional methods, is performed in a vacuum, increases throughput and reduces costs. By way of illustration, an electron beam gun provides great electrical power at low cost, which makes it possible to produce both a great amount of material vapor and to emit a great amount of solid particles into a vacuum, in which these particles are coated by means of the material vapor. The solid particles may be applied to a surface to be functionalized, for example, after coating by means of a wet-chemical coating process.

According to various embodiments, a transporting device which by way of illustration makes it possible to transport the solid particles with a high throughput into the vacuum or out of it, and thereby provides a sufficiently great gas separation (vacuum separation) is provided for the solid particles (solid particle transporting device).

By way of illustration, the solid particle transporting device prevents excessive gas exchange with the surroundings from taking place during the transporting of the solid particles into the vacuum or out of it. For example, the gas exchange may be less than a pumping capability applied to the vacuum, which may be provided by means of a pump arrangement.

According to various embodiments, a method may comprise the following: producing a vacuum in a coating region and in a collecting region; emitting solid particles with a first main direction of propagation through the coating region into the collecting region; evaporating a coating material (may also be referred to as evaporation material) with a second main direction of propagation into the coating region, the first main direction of propagation and the second main direction of propagation extending at an angle to one another in such a way that the coating material is evaporated past the collecting region.

The emission of solid particles may take place according to various embodiments by means of introducing electrons into the solid particles for the electrostatic charging of the solid particles, so that a force brought about by the electrostatic charging accelerates the solid particles in the direction of the coating region and/or separates them from one another. For example, the solid particles, which may for example take the form of bulk material, may be electrostatically charged, so that they repel one another.

The introduction of electrons may take place according to various embodiments by means of an electron beam.

According to various embodiments, the electron beam may be directed at a container in which the solid particles are arranged. As an alternative, or in addition, the electron beam may be directed at the solid particles.

According to various embodiments, the solid particles in the coating region may be coated with the coating material.

According to various embodiments, the method may also comprise: collecting the coated solid particles in the collecting region after they have crossed through the coating region.

According to various embodiments, the method may also comprise: collecting the solid particles in the collecting region after they have crossed through the coating region by means of a collecting device and/or by means of a substrate.

According to various embodiments, the method may also comprise: transporting the solid particles between the collecting region and a region (for example an atmospheric region) which is at a pressure greater than a vacuum during the emission of the solid particles. For example, the method may also comprise: transporting the solid particles by means of the collecting device into a region which is at a pressure (for example gas pressure) greater than a vacuum. The region may be at a pressure of at least one order of magnitude (for example more than approximately two, three, four, five, six, seven, eight, nine or for example more than approximately ten orders of magnitude) greater than the collecting region.

According to various embodiments, the method may also comprise: transporting the solid particles between an emission region and a region (for example an atmospheric region) which is at a pressure greater than a vacuum during the emission of the solid particles from the emission region with the first main direction of propagation through the coating region into the collecting region. For example, the method may also comprise: transporting solid particles that are to be emitted into the emission region, from which the solid particles are emitted through the coating region during the emission of the solid particles. The region may be at a pressure of at least one order of magnitude (for example more than approximately two, three, four, five, six, seven, eight, nine or for example more than approximately ten orders of magnitude) greater than the emission region.

According to various embodiments, the emission of the solid particles and/or the evaporation of the coating material may take place by means of precisely one electron beam source (at least precisely one electron beam gun) or by means of multiple electron beam sources (for example multiple electron beam guns).

According to various embodiments, a processing arrangement may comprise the following: a vacuum chamber with a coating region and a collecting region; a solid particle source, which is configured to emit solid particles with a first main direction of propagation through the coating region into the collecting region; a material vapor source, which is configured to evaporate a coating material with a second main direction of propagation into the coating region; the first main direction of propagation and the second main direction of propagation extending at an angle to one another in such a way that the material vapor source evaporates the coating material past the collecting region.

According to various embodiments, the solid particle source may be configured to bring about the emission by means of introducing electrons into the solid particles for the electrostatic charging of the solid particles, so that a force brought about by the electrostatic charging accelerates the solid particles in the direction of the coating region and/or separates them from one another.

According to various embodiments, the solid particle source may comprise an electron beam source which is configured for introducing the electrons into the solid particles.

According to various embodiments, the electron beam source may be configured for irradiating a container with electrons in which the solid particles are arranged. As an alternative or in addition, the electron beam source may be configured for irradiating the solid particles.

According to various embodiments, the material vapor source may be configured for coating the solid particles in the coating region with the coating material.

According to various embodiments, a processing arrangement may comprise the following: a collecting device and/or a substrate transporting device which are made to extend in the collecting region.

According to various embodiments, the collecting device may be configured for collecting the coated solid particles in the collecting region after they have crossed through the coating region.

According to various embodiments, the substrate transporting device may be configured for transporting a substrate through the collecting region in such a way that the coated solid particles are collected by means of the substrate in the collecting region after they have crossed through the coating region.

According to various embodiments, the collecting device may be configured for transporting the solid particles into a region outside the vacuum chamber.

According to various embodiments, the solid particle source may be configured for transporting the solid particles that are to be emitted into the coating region out of a region outside the vacuum chamber.

According to various embodiments, a processing arrangement may comprise the following: a solid particle transporting device which is configured to supply a container of the solid particle source with solid particles while it is emitting solid particles.

According to various embodiments, the solid particle source and the material vapor source may comprise precisely one common electron beam source; or the solid particle source and the material vapor source may each comprise at least one electron beam source.

According to various embodiments, a method may comprise the following: producing a vacuum in a vacuum chamber; and transporting solid particles into the vacuum chamber (or into the vacuum) and/or out of it by means of a conveying screw, which brings about a vacuum separation.

According to various embodiments, a solid particle source may comprise the following: a container (may also be referred to as a particle container) which has a region (may also be referred to as an emission region) for receiving solid particles; at least one electron beam source for irradiating the container and/or the region; and a conveying screw, which brings about a vacuum separation for feeding solid particles into the container.

According to various embodiments, the processing arrangement may comprise the following: a vacuum chamber and a transporting device for transporting solid particles (solid particle transporting device) into the vacuum chamber and/or out of it; the transporting device comprising: a transporting channel, which extends through a chamber wall of the vacuum chamber; and a rotatably mounted conveying screw, which is arranged in the transporting channel and with it forms a gas separation gap for bringing about a vacuum separation (may also be referred to as gas separation). For example, a solid particle transporting device may comprise or be formed by a screw conveyor.

According to various embodiments, a method may comprise the following: providing two regions, which differ in at least one of the following; a gas pressure by more than approximately one order of magnitude (for example more than approximately two, three, four, five, six, seven, eight, nine or for example more than approximately ten orders of magnitude) and/or a chemical gas composition (for example in a gaseous constituent); and transporting solid particles between the two regions by means of a conveying screw, which brings about a vacuum separation between the two regions. One of the regions may for example be a vacuum region.

According to various embodiments, a processing arrangement may be configured for providing the two regions and comprise the conveying screw.

According to various embodiments, the solid particles in a collecting region may form a layer and/or a bulk material (a loose arrangement of the solid particles).

According to various embodiments, the emission of the solid particles may comprise: introducing electrons into the solid particles (for example by means of an electron beam gun) that are arranged in the emission region, for the electrostatic charging of the solid particles in such a way that a force brought about by the electrostatic charging separates the solid particles from one another and accelerates them out of the emission region, for example in the direction of the coating region.

According to various embodiments, the processing arrangement and/or the coating device may also comprise: a control system, which is configured for controlling an electrostatic charging of the solid particles (and/or of the electron beam gun) in such a way that a force brought about by the electrostatic charging separates the solid particles from one another and accelerates them out of the emission region, for example in the direction of the coating region, for example for coating the solid particles in the coating region.

According to various embodiments, the coating region may be arranged between the collecting region and the solid particle source.

According to various embodiments, the evaporation of the coating material may take place past the collecting region. In other words, the material vapor source may be arranged and aligned in such a way in relation to the collecting region that the material vapor source evaporates the coating material past the collecting region, for example along the second main direction of propagation.

According to various embodiments, a solid particle transporting device may comprise at least one of the following: a container (may also be referred to as a screw trough) inside or outside the vacuum chamber (or the vacuum) for keeping and/or receiving solid particles; optionally a covering for the container (also referred to as a trough covering); a conveying screw for transporting solid particles into the container or out of it; a drive device for driving the conveying screw; and a transporting channel for receiving the conveying screw.

The conveying screw may be rotatably mounted by means of a bearing device. The bearing device may for example comprise or be formed by one or more rolling bearings. Optionally, the bearing device may comprise one or more seals.

The conveying screw may comprise a shaft and a screw thread, which extends around the shaft.

The transporting channel may comprise a channel entry and a channel exit.

According to various embodiments, a conveying screw may be used for transporting solid particles into a vacuum chamber or out of it.

According to various embodiments, a conveying screw may be used for transporting solid particles between two regions that differ in at least one of the following: a gas pressure by more than one order of magnitude (for example more than approximately two, three, four, five, six, seven, eight, nine or for example more than approximately ten orders of magnitude) and/or a chemical gas composition (for example in a gaseous constituent); the conveying screw bringing about a gas separation between the two regions (so that the difference between the two regions can be maintained).

According to various embodiments, the solid particles may be coated with the coating material (for example in the coating region). In other words, a layer (may also be referred to as a solid particle layer or coating) may be formed on each solid particle. The layer may comprise or be formed by the coating material. For example, the layer may comprise or be formed by an oxide of the coating material. The layer does not necessarily have to enclose a solid particle completely. For example, the layer may partially cover the solid particle, for example more than approximately 10% and/or less than approximately 90% (of the surface of the solid particle), for example more than approximately 20% and/or less than approximately 80%, for example more than approximately of approximately 30% and/or less than approximately 70%.

A temperature of the solid particles during the introduction of the electrons and/or during the coating may be less than a vapor-pressure temperature (i.e. a temperature at which the vapor pressure of the solid particles is equal to the ambient pressure of the solid particles in the vacuum chamber) of the solid particles and/or be less than a state-of-aggregation transition temperature (for example an evaporation temperature, a melting temperature and/or a sublimation temperature) of the solid particles. It can in this way by way of illustration be prevented that the solid particles melt, sublimate, sinter together and/or evaporate. By way of illustration, the solid particles can be electrostatically charged by means of the introduction of the electrons without bringing their temperature over the state-of-aggregation transition temperature and/or vapor-pressure temperature. The thermal power loss may depend on the temperature of the solid particles.

According to various embodiments, the solid particles may additionally be cooled, for example by means of the container. As an alternative or in addition, a power of the electrons (for example electrical and/or kinetic power), i.e. a power introduced by the electrons, may be configured in such a way that the temperature of the solid particles during the introduction of the electrons and/or during the coating is greater than their state-of-aggregation transition temperature and/or vapor-pressure temperature. For example, the power introduced by means of the electrons may be less than a thermal power loss of the solid particles.

Within the scope of this description, the solid particles may be understood as meaning particles (by way of illustration grains or granules) which comprise or are formed by a solid material, i.e. matter in a solid state of aggregation (the matter being able to comprise multiple atoms and/or molecules). The solid particles may have an extent (by way of illustration particle size) greater than approximately 5 nm, for example greater than approximately 0.1 μm and/or less than approximately 1 mm, for example less than approximately 500 μm, for example in a range from approximately 10 nm to approximately 500 μm, for example in a range from approximately 100 nm to approximately 100 μm, for example in a range from approximately 200 nm to approximately 10 μm, or in a range from approximately 0.1 μm to approximately 1 mm, for example in a range from approximately 1 μm to approximately 50 μm or in a range from approximately 10 μm to approximately 250 μm, for example approximately 10 μm. The solid particles may by way of illustration form granules or a powder. The extent of the solid particles may be their average extent, for example averaged over all the solid particles and/or averaged for each solid particle individually. The average extent of an individual solid particle may by way of illustration correspond to a diameter of a sphere that has the volume of the solid particle.

According to various embodiments, the solid particles may be arranged in a container (may also be referred to as a particle container) which comprises an at least partially electrically conductive container wall. The introduction of electrons into the solid particles may take place indirectly by way of the container wall. In other words, the introduction of electrons into the solid particles may take place from the container wall, for example by the latter being irradiated by means of an electron beam. It can in this way be achieved for example that the electrons are distributed by means of the container wall, which reduces an electrical current density that is brought about by the introduction of electrons into the solid particles. Consequently, local heating of the solid particles, for example local melting or sintering together brought about as a result, can by way of illustration be reduced and/or prevented. As an alternative or in addition, the introduction of electrons may take place directly into the solid particles, for example by the latter being irradiated by means of an electron beam.

According to various embodiments, the method may also comprise: removing electrons from the solid particles during the introduction of electrons into the solid particles. The introduction and/or the removal may take place in an open-loop or closed-loop controlled manner, for example by means of a control system. In this way, an electrical potential of the solid particles which is brought about by the introduction and/or the removal of electrons can be controlled in an open-loop or closed-loop manner. By way of illustration, part of the electrical charge which is introduced by the introduction of electrons into the solid particles is at least partially removed again by means of the removal of electrons.

According to various embodiments, the control system may comprise a forwardly directed controlled system, and consequently by way of illustration implement a sequence control which converts an input variable into an output variable. The controlled system may however also be part of a control loop, so that a closed-loop control is implemented. In contrast with the purely forward open-loop control, the closed-loop control has a continuous influence of the output variable on the input variable, which is brought about by the control loop (feedback). According to various embodiments, a closed-loop control may be used instead of the open-loop control and closed-loop controlling may be performed instead of open-loop controlling.

According to various embodiments, the method may also comprise: open-loop controlling and/or closed-loop controlling (for example by means of open-loop or closed-loop control) of an electrical potential difference between the collecting device or the substrate and the particle container. The electrical potential of the solid particles may correspond to the electrical potential of the particle container. For example, an electrical potential of the collecting device or of the substrate and/or an electrical potential of the solid particles may be controlled in an open-loop and/or closed-loop manner. For example, an electrical voltage applied to the collecting device or the substrate (i.e. an electrical potential difference in relation to an electrical reference potential) may be controlled in an open-loop or closed-loop manner. As an alternative or in addition, an electrical voltage applied to the solid particles (i.e. an electrical potential difference in relation to an electrical reference potential) may be controlled in an open-loop or closed-loop manner. The electrical reference potential may for example be provided by a vacuum chamber. As an alternative, the electrical potential difference between the collecting device or the substrate and the solid particles may also be controlled in an open-loop or closed-loop manner on a floating basis (i.e. independently of the electrical reference potential).

According to various embodiments, the solid particles may have a negative electrical charge on leaving the region. As a result, a controlled take-up and/or deflection of the solid particles by means of the collecting device or the substrate can take place by means of an electrical BIAS voltage (electrical potential difference between the collecting device or the substrate and the solid particles or the container).

The electron beam source may comprise an emission area (for example provided by means of a cathode, for example by means of a thermionic cathode and/or a field emission cathode) for emitting electrons. The electron beam source may also comprise a beam forming unit. The beam forming unit may comprise at least one electrode or multiple electrodes and/or one coil or multiple coils. The beam forming unit may be configured for forming a beam (electron beam) from the emitted electrons. An electron beam gun may comprise an electron beam source and a deflecting arrangement. The deflecting arrangement may be configured for deflecting the electron beam according to one or more deflecting parameters, for example to irradiate the region and/or the container by means of the electron beam. The deflecting arrangement may comprise at least one electrode or multiple electrodes and/or one coil or multiple coils.

The electron beam source may be configured to provide an electron beam of more than approximately 5 kW, for example more than approximately 10 kW, for example more than approximately 30 kW, for example more than approximately 40 kW, for example more than approximately 50 kW.

According to various embodiments, the control system may be configured for controlling an amount of electrons that is introduced into the solid particles; for controlling an amount of electrons that is removed from the solid particles; for controlling an electrical potential difference between the collecting device or the substrate and the particle container; and/or for controlling the coating on the basis of an amount of electrons that is introduced into the solid particles and/or that is removed from the solid particles.

According to various embodiments, the method may also comprise: controlling (for example by means of open-loop control) a propagation characteristic of the solid particles that are emitted away from the container and/or through the coating region. The propagation characteristic may comprise at least one of the following: the first main direction of propagation, an average deviation from the first main direction of propagation (for example a solid angle into which the solid particles propagate), a main rate of propagation, or an average deviation from the main rate of propagation. As an alternative or in addition to the main rate of propagation, a main impulse and/or a main kinetic energy of the solid particles and/or an average diversion therefrom may be used.

The layer formed by means of the coating of the solid particles may have a layer thickness (for example an extent transversely in relation to the surface of the solid particles) greater than approximately 0.1 nm, for example greater than approximately 1 nm, for example greater than approximately 10 nm. As an alternative or in addition, the layer may have a thickness (layer thickness) of less than the extent of the solid particles, for example of less than approximately 10 nm, for example less than approximately 5 nm, for example less than approximately 2.5 nm, for example less than approximately 1 nm, for example less than approximately 0.5 nm, for example in a range from approximately 0.1 nm to approximately 1 nm.

According to various embodiments, the container may be kept electrically insulating (for example electrically insulated from the vacuum chamber). Then, a (for example uncontrolled) removal of electrons, for example along with the conventional emission characteristic of secondary electrons, from the container can be reduced or prevented and/or only take place by means of the particle emission. For example, the removal of the electrons can only take place by means of the particles accelerated away from the container (which are by way of illustration electrically charged).

According to various embodiments, the solid particles and/or the coating material may comprise a rechargeable battery active material, a fuel cell active material, a solar cell active material, a catalyst material and/or a solid electrolyte.

An electrolyte may be understood as meaning a material which in the solid (solid electrolyte), liquid or dissolved state is dissociated in ions, so that the latter can move in a directed manner under the influence of an electric field. A rechargeable battery active material may be understood as meaning a material which takes up or gives off electrical charges under a chemical reaction (in other words which converts electrical energy into chemical energy, and vice versa). A fuel cell active material may be understood as meaning for example a material which is applied to a woven fabric (mesh, nonwoven) as a microporous layer (MPL) in the form of a gas diffusion layer. A catalyst material may be understood as meaning a material which increases a rate of reaction by lowering the activation energy of a chemical reaction without at the same time being consumed itself. A solar cell active material may be understood as meaning a material which converts radiation energy (energy of electromagnetic radiation, for example light) into electrical energy, and vice versa.

The solid electrolyte may for example comprise or be formed by one of the following: yttrium-stabilized zirconium (YSZ), zirconium dioxide (ZrO₂), yttrium oxide (Y₂O₃), lithium-phosphorus oxynitride (LiPON) and/or a sulfide glass.

For example, the solid particles and/or the coating material may comprise or be formed by at least one material of the following materials: a metal; a transition metal, an oxide (for example a metal oxide or a transition metal oxide); a dielectric; a polymer (for example a carbon-based polymer or a silicon-based polymer); an oxynitride; a nitride; a carbide; a ceramic; a metalloid (for example carbon); a perovskite; a glass or vitreous material (for example a sulfide glass); a semiconductor; a semiconductor oxide; a semi-organic material, and/or an organic material. The solid particles may differ from the coating material in at least one chemical composition.

The carbon may comprise or be formed by at least one of the following carbon configurations: graphite; amorphous carbon; tetrahedral carbon; diamond-like carbon; fullerene; diamond; carbon nanotubes; amorphous-tetrahedral carbon; and/or nanocrystalline carbon; for example nanocrystalline graphite. Optionally, hydrogen may be taken up in the carbon (for example a carbon configuration mixed with hydrogen).

According to various embodiments, the solid particles may be coated with the coating material, for example with a metal coating (for example carbon black particles coated with platinum and/or carbon black particles coated with ruthenium may be provided). According to various embodiments, the coating of the solid particles may be provided by means of coevaporation. According to various embodiments, the coating material may comprise or be formed by at least one metal (for example nickel, titanium and/or chromium). A material of the coating material may be different from a material of the solid particles.

Within the scope of this description, a metal (also referred to as a metallic material) may comprise (or be formed by) at least one metallic element (i.e. one or more metallic elements), for example at least one element from the following group of elements: copper (Cu), iron (Fe), titanium (Ti), nickel (Ni), silver (Ag), chromium (Cr), platinum (Pt), ruthenium (Ru), gold (Au), magnesium (Mg), aluminum (Al), zirconium (Zr), tantalum (Ta), molybdenum (Mo), tungsten (W), vanadium (V), barium (Ba), indium (In), calcium (Ca), hafnium (Hf), samarium (Sm), silver (Ag), and/or lithium (Li). Furthermore, a metal may comprise or be formed by a metallic compound (for example an intermetallic compound or an alloy), for example a combination of at least two metallic elements (for example from the group of elements), such as for example bronze or brass, or for example a combination of at least one metallic element (for example from the group of elements) and at least one nonmetallic element (for example carbon), such as for example steel.

Within the scope of this description, a plastic may be understood as meaning an organic substance in polymer form (i.e. a polymer), for example polyamide, polyethylene terephthalate (PET), polytetrafluoroethylene (PTFE), or electrically conductive polymer.

A first active material of a battery (for example its electrode, for example the cathode) may for example comprise or be formed by nickel manganese cobalt (NMC) (for example in a lithium-iron-phosphate rechargeable battery cell), comprise or be formed by lithium-iron phosphate (LFP) (for example in a lithium-iron-phosphate rechargeable battery cell), comprise or be formed by lithium-manganese oxide (LMO) (for example in a lithium-manganese-oxide rechargeable battery cell) and/or comprise or be formed by lithium-nickel-manganese oxide (LNMO) (for example in a lithium-titanate rechargeable battery cell). For a lithium-ion rechargeable battery, the active material may also be referred to as a lithium compound active material.

A second active material of a battery (for example its counterelectrode, for example the anode) may differ from the first active material of the electrode. The second active material may for example comprise or be formed by graphite (or carbon in another configuration), comprise or be formed by nanocrystalline and/or amorphous silicon, comprise or be formed by lithium-titanate (spinel) oxide (Li₄Ti₅O₁₂ or LTO), comprise or be formed by metallic lithium or comprise or be formed by tin dioxide (SnO₂).

Optionally, binder materials conventional in the area of lithium-ion batteries in the form of particles, for example PVDF homopolymer, CMC (carboxymethyl cellulose) or HPMC (hydroxypropyl methylcellulose), may be provided with a metal-like and/or carbon-containing functional layer to achieve improved electrical conductivity and/or an improved barrier effect. In other words, according to various embodiments, the particles may be coated with a metallic and/or a carbon-containing material.

According to various embodiments, the collecting device may be configured to emit the coated solid particles into a further vacuum region, for example for coating a substrate in the further vacuum region with the solid particles. As an alternative, part of the solid particles collected by means of the collecting device may be fed back to the solid particle source (for example by means of a solid particle transporting device).

Optionally, the processing arrangement may comprise a further material vapor source, which is configured to evaporate (for example thermally) a further coating material in the direction of the substrate transporting device, for example into the collecting region. In this way, the coating of the substrate with the solid particles and a coating of the substrate with the further coating material can take place in the collecting region, for example simultaneously.

According to various embodiments, the coated solid particles may be introduced into a liquid or pasty carrier and be applied together with the latter to a substrate (wet-chemical coating), for example outside the vacuum chamber.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a method according to various embodiments in a schematic flow diagram;

FIG. 2A and FIG. 2B respectively show a processing arrangement according to various embodiments in a schematic side view or a cross-sectional view;

FIG. 3A and FIG. 3B respectively show a processing arrangement according to various embodiments in a schematic side view or cross-sectional view;

FIG. 4A and FIG. 4B respectively show a processing arrangement according to various embodiments in a schematic side view or cross-sectional view;

FIG. 5 shows a method according to various embodiments in a schematic flow diagram;

FIG. 6 shows a method according to various embodiments in a schematic flow diagram;

FIG. 7 shows a solid particle source according to various embodiments in a schematic plan view or cross-sectional view;

FIG. 8 shows the solid particle source from FIG. 7 in a schematic perspective view;

FIG. 9 shows the solid particle source from FIG. 7 in a schematic view of a detail;

FIG. 10 shows a solid particle source according to various embodiments in a schematic perspective view;

FIG. 11, FIG. 12, FIG. 13 and FIG. 14 respectively show a processing arrangement according to various embodiments in a schematic perspective view; and

FIG. 15A, FIG. 15B and FIG. 16 respectively show a processing arrangement according to various embodiments in a schematic perspective view.

### DETAILED DESCRIPTION

In the following detailed description, reference is made to the accompanying drawings, which form part of this description and in which specific embodiments in which the invention can be carried out are shown for purposes of illustration. In this respect, directional terminology such as for instance “at the top”, “at the bottom”, “at the front”, “at the rear”, “front”, “rear”, etc. is used with reference to the orientation of the figure(s) described. Since components of embodiments may be positioned in a number of different orientations, the directional terminology serves for purposes of illustration and is in no way restrictive. It goes without saying that other embodiments may be used and structural or logical changes may be made without departing from the scope of protection of the present invention. It goes without saying that the features of the various embodiments described herein by way of example can be combined with one another, unless otherwise specifically stated. The following detailed description is therefore not to be interpreted in a restrictive sense.

In the course of this description, the terms “connected” and “coupled” are used for describing both a direct connection and an indirect connection and both a direct coupling and an indirect coupling. In the figures, identical or similar elements are provided with identical designations, wherever appropriate.

According to various embodiments, a high-rate electron beam evaporation is provided for functionalizing solid particles by means of collective electron-beam-induced emission of solid particles.

According to various embodiments, functionalized solid particles, which can be used for example in a wide variety of applications, may be provided. By way of example, the use for battery materials is described below. The nature of the active material in a battery (for example liquid-electrolyte-based lithium-ion batteries and/or solid-electrolyte-based (solid-state/all-solid-state) lithium-ion batteries, can define the capacity of the battery, and thereby their volume densities, energy density and power density. The active material may for example be used as electrode material.

For example, the chemical composition of the active material, for example as a constituent of the anode, the cathode, and/or the electrolyte (for example liquid electrolyte and/or solid electrolytes) defines the ionic or electrical properties of the battery. For example, on the cathode side, the electrical attachment of the solid particles (also referred to herein as particles) to one another and/or their interaction with a current collector of the battery can be improved by means of coated solid particles.

For example, active material of the anode may comprise or be formed by lithium (Li), carbon (C) and/or silicon (Si), for example LiC₆ and/or lithiated graphite. For example, an active material of the cathode may comprise or be formed by lithium-iron phosphate (LFP), lithium-manganese oxide (LMO), lithium-manganese-nickel oxide (LMNO), lithium-cobalt oxide (LCO), lithium-nickel-cobalt-manganese oxide (LNCM oxide), lithium-nickel-cobalt-aluminum oxide (LNCA oxide) and/or high-voltage spinel (HV spinel). For example, a liquid electrolyte may comprise or be formed by lithium-phosphorus fluoride (LiPF₆), lithium-boron fluoride (LiBF₄) and/or lithium-chlorine oxide (LiClO₄). Optionally, the liquid electrolyte may comprise an organic solvent (such as for example ethylene carbonate and/or dimethyl carbonate). For example, a solid electrolyte may comprise or be formed by lithium-phosphorus oxinitride (LiPON), lithium-diphosphorus pentasulfide (LISPS, for example Li₂SP₂S₅).

According to various embodiments, a functionalization (by means of coating the solid particles) which for example increases the power density of a battery may be provided. For example, the solid particles may comprise or be formed by aluminum, aluminum oxide, lithium, nickel, magnesium and/or cobalt, for example in the form of a chemical compound comprising lithium, nickel, magnesium and cobalt, for example an oxide thereof (for example lithium-nickel-manganese-cobalt oxide). For example, a layer which is applied to the solid particles may comprise or be formed by lithium (Li) and/or niobium (Ni), for example in the form of a chemical compound comprising lithium (Li) and niobium (Ni), for example an oxide thereof (for example LiNbO₃).

According to various embodiments, a collective emission of solid particles may be provided by means of electron-beam-induced (EB-induced), for example indirect, solid particle emission. The solid particles may after emission cross through (penetrate) one or more vapor clouds (i.e. a material vapor or multiple material vapors) of an evaporation taking place at the same time as emission (simultaneously) (co-evaporation). While crossing the material vapor, the surface of the solid particles may be coated, for example with the coating material. The coating material may bring about a functionalization of the solid particles, i.e. their chemical and/or physical properties change. The coating may take place according to various embodiments under vacuum conditions (i.e. in a vacuum region). The number of material vapors may differ in their chemical composition.

As a difference from cathode sputtering, the emission of the solid particles (solid particle emission, may also be referred to as atomization of the solid particles) does not transform the solid particles into a gaseous state (i.e. they substantially retain their state of aggregation). In other words, the solid particles remain in the solid state (state of aggregation) during the atomization of the solid particles.

By means of the EB-induced solid particle emission, any desired solid particles in terms of size and type of material can be emitted into the coating region. For example, the solid particles may comprise or be formed by a plastic, for example a fluorine-based polymer material (such as for example polytetrafluoroethylene—PTFE). As an alternative or in addition, the solid particles may comprise or be formed by carbon in a carbon modification, for example graphite. For example, the solid particles may comprise or be formed by a composite material, for example a polymer-based (for example PTFE) composite material and/or a carbon composite (for example a graphite composite).

As an alternative or in addition, other powdered materials, for example in the form of active material for the electrodes in battery systems, may be emitted into the coating region (i.e. be transferred into the vacuum).

According to various embodiments, a gravimetric, morphological and/or chemical modification of the solid particles cannot be brought about by means of the emission of the solid particles. In other words, the solid particles can retain their gravimetric, morphological and/or chemical properties.

The solid particle emission (also referred to as displacement) can be brought about by a static charging of solid particles. By way of illustration, a certain number of negative charges (electrons) can remain in the solid particles during the flight phase (trajectory) of the solid particles, for example through the coating region (i.e. in the vacuum). As a result, a weak physical modification of the solid particles may be brought about.

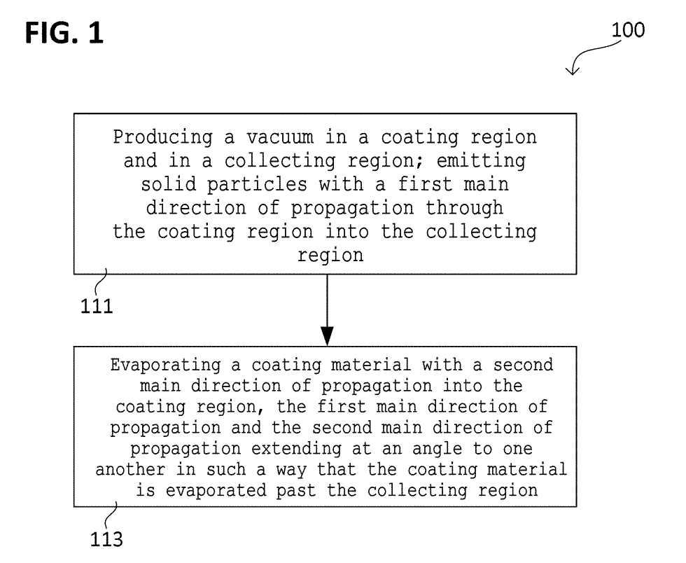

FIG. 1 illustrates a method 100 according to various embodiments in a schematic flow diagram.

The method 100 may comprise in 111: producing a vacuum in a coating region and in a collecting region; emitting solid particles with a first main direction of propagation through the coating region into the collecting region. The method may also comprise in 113: evaporating a coating material (may also be referred to as co-evaporation) with a second main direction of propagation into the coating region, the first main direction of propagation and the second main direction of propagation extending at an angle to one another in such a way that the coating material is evaporated past the collecting region.

Optionally, the coating of the solid particles may be performed using a plasma (may also be referred to as plasma-assisted coating).

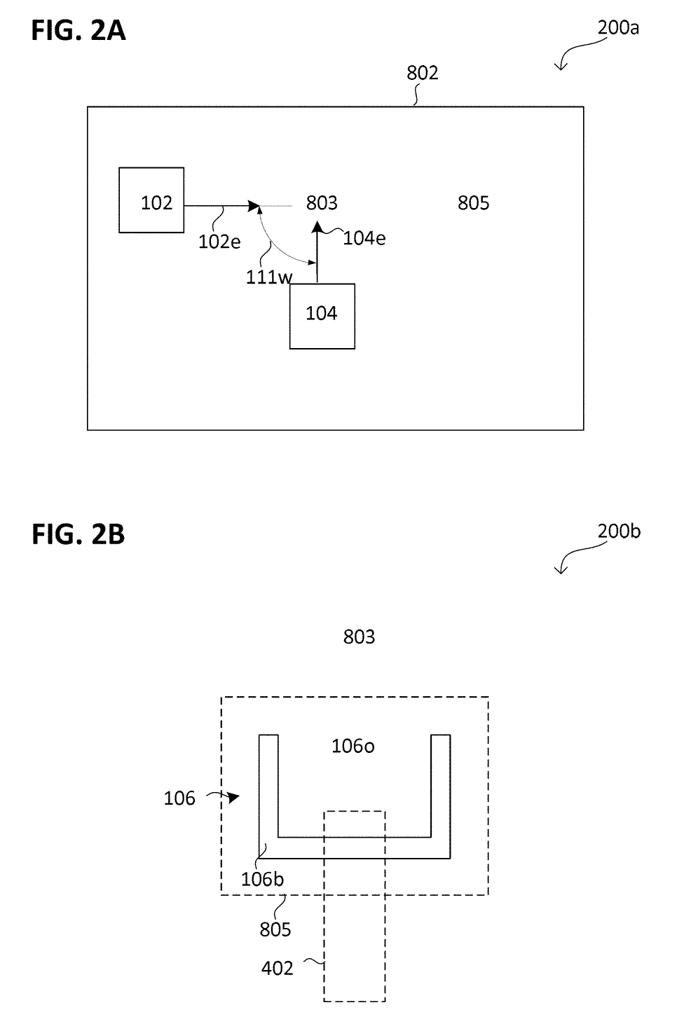

FIG. 2A illustrates a processing arrangement 200a according to various embodiments in a schematic side view or cross-sectional view (for example in section along the two main directions of propagation 102e, 104e).

According to various embodiments, the processing arrangement 200a may comprise a vacuum chamber 802. In the vacuum chamber 802, a coating region 803 and a collecting region 805 may be arranged. The coating region 803 and/or the collecting region 805 may be a vacuum region.

Furthermore, the processing arrangement 200a may be arranged a solid particle source 102. The solid particle source 102 may be configured to emit solid particles with a first main direction of propagation 102e through the coating region 803 into the collecting region 805.

Furthermore, the processing arrangement 200a may comprise a material vapor source 104 (may also be referred to as an evaporation device 104). The material vapor source 104 may be configured to evaporate a coating material with a second main direction of propagation 104e into the coating region 803. The material vapor source 104 may be configured for thermally evaporating the coating material.

According to various embodiments, the first main direction of propagation 102e and the second main direction of propagation 104e may extend at an angle 111w to one another. It can in this way be achieved that the material vapor source 104 evaporates the coating material past the collecting region 805, for example all the more the closer the angle 111w is to 90°. Depending on the prevailing conditions, however, the angle may also deviate from 90°. The angle 111w may lie in a range from approximately 10° to approximately 180°, for example in a range from approximately 30° to approximately 160°, for example in a range from approximately 45° to approximately 135°, for example in a range from approximately 60° to approximately 120°, for example in a range from approximately 80° to approximately 100°, for example be approximately 90°.

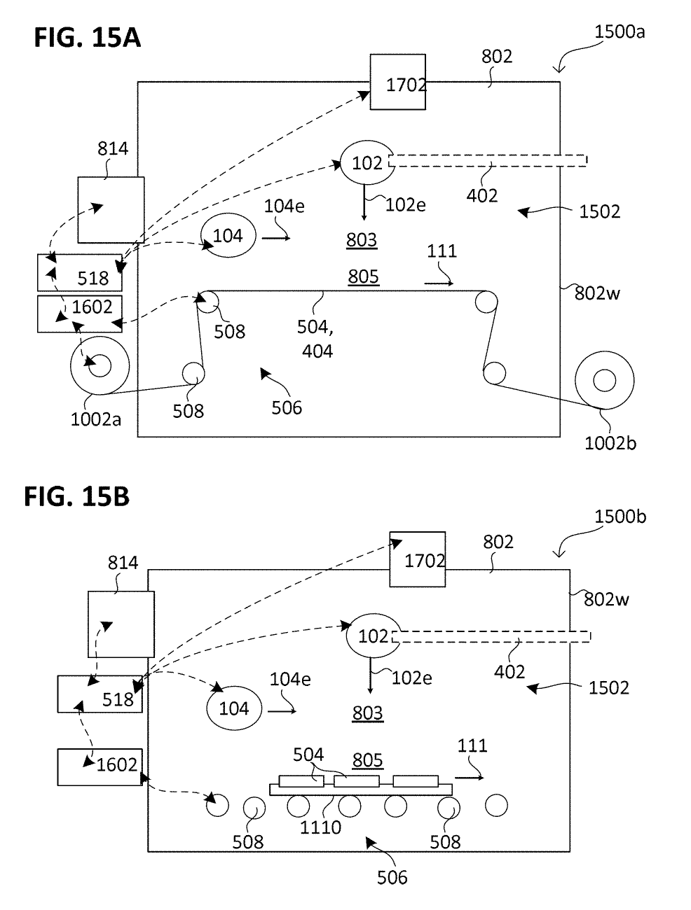

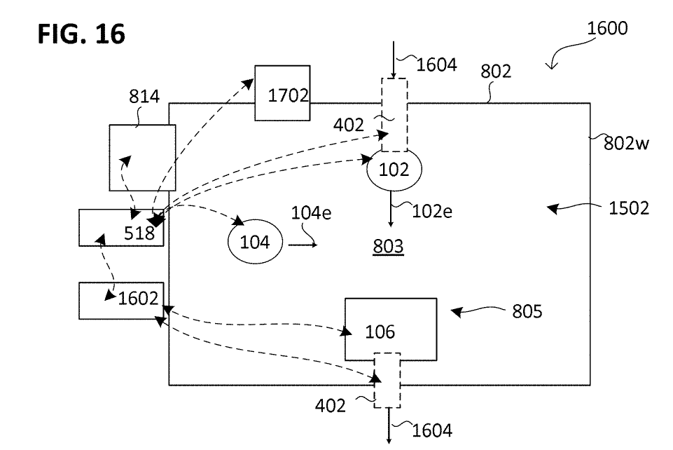

According to various embodiments, controlling (for example by means of open-loop control) a propagation characteristic of the solid particles which is emitted away from the solid particle source 102 may take place, for example by means of a control system 518 (compare for example FIG. 15A).

The propagation characteristic may comprise at least one of the following: the first main direction of propagation 102e, an average deviation from the first main direction of propagation 102e (for example a dihedral angle into which the solid particles propagate), a main rate of propagation, or an average deviation from the main rate of propagation.

According to various embodiments, the main rate of propagation (for example within the coating region 803) may lie in a range from approximately to approximately 0.1 meter per second to 50 m/s, for example in a range from approximately 1 m/s to approximately 10 m/s.

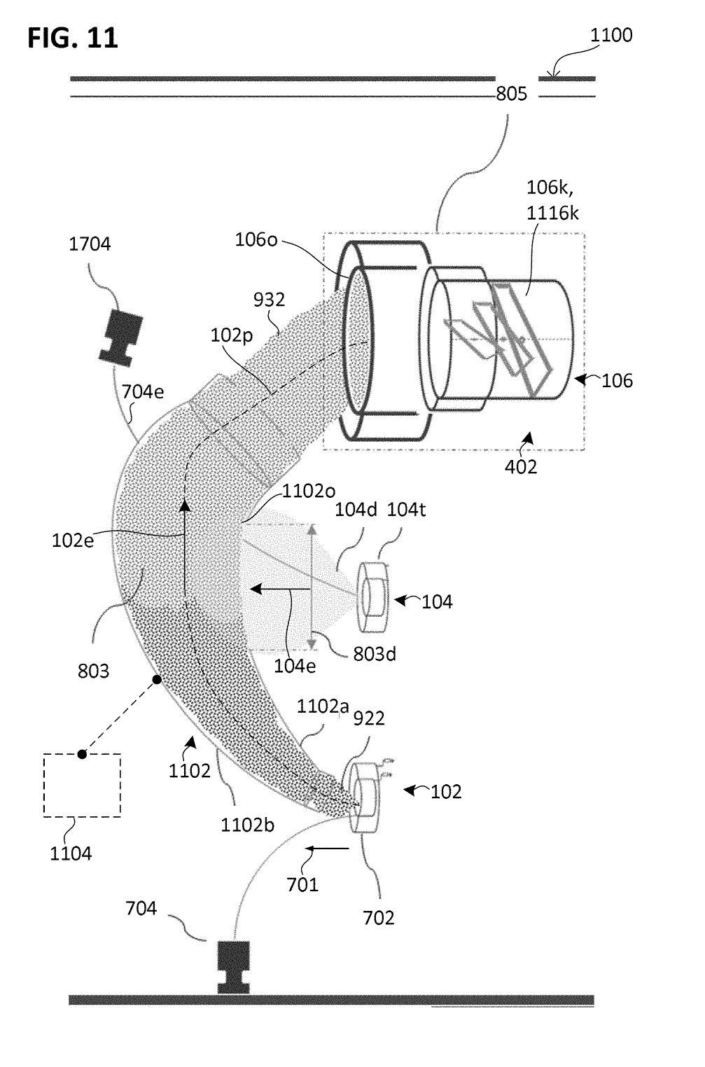

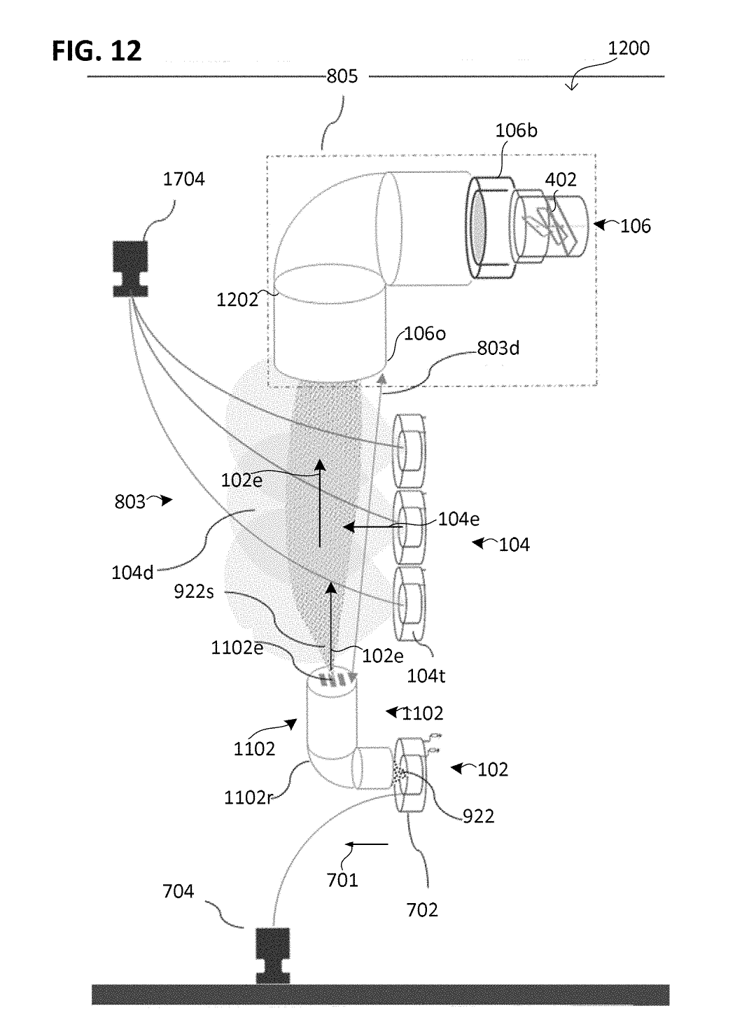

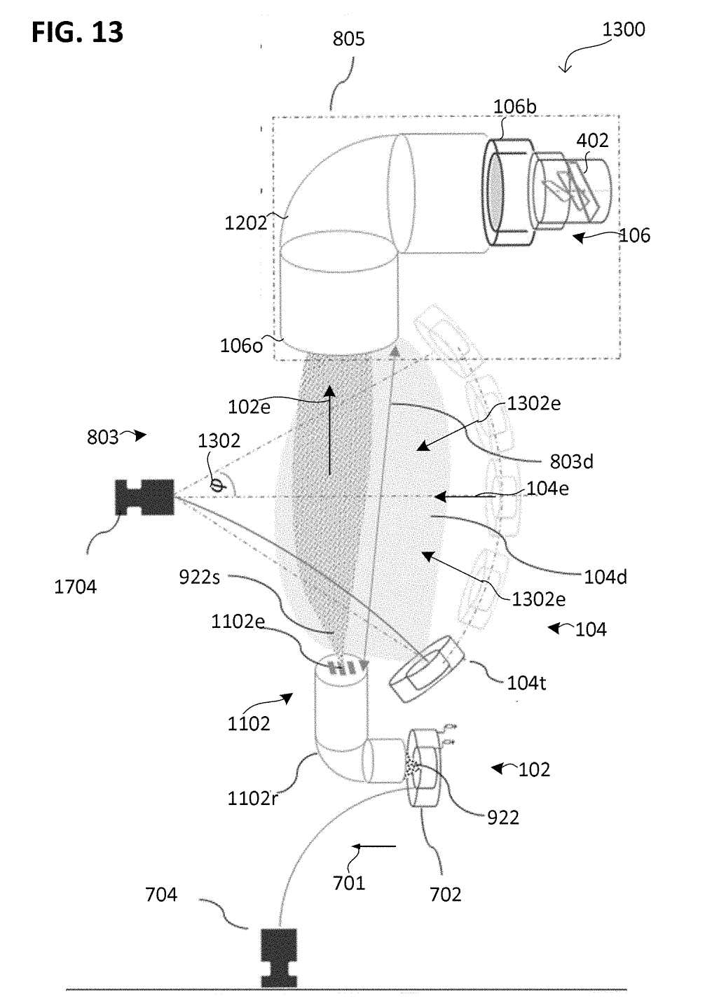

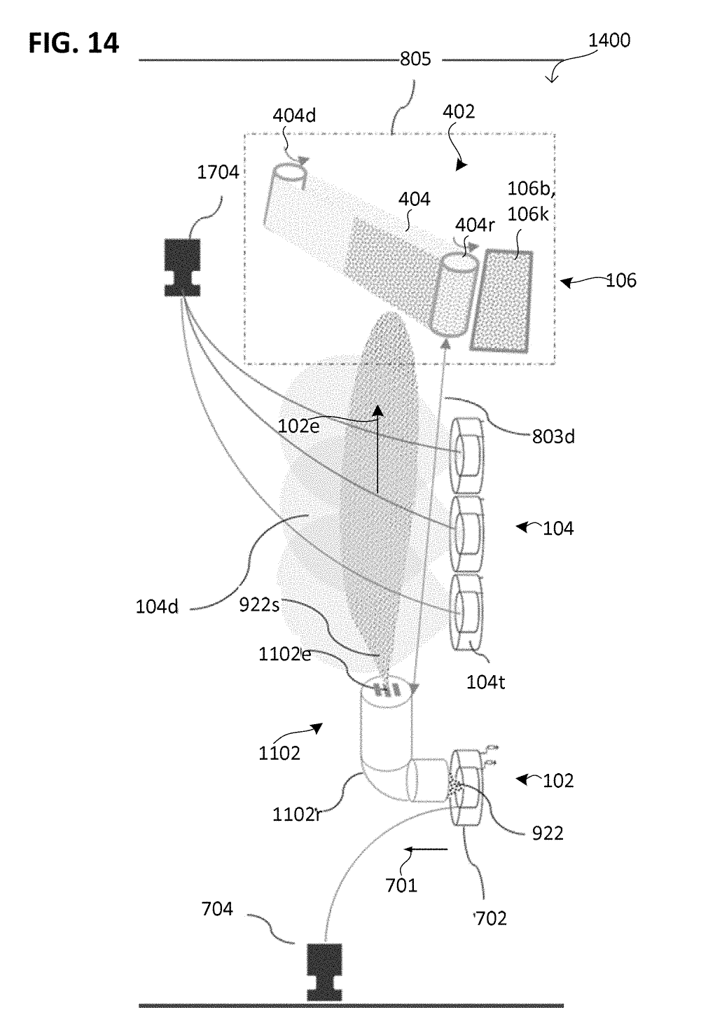

For example, a focusing of the solid particles may take place, for example in that the average deviation from the first main direction of propagation 102e is reduced. As an alternative or in addition, a guiding of the solid particles may take place, for example in that a spatial course of a path 102p (compare for example FIG. 11) along which the solid particles move is defined (for example by means of deflecting the solid particles). The first main direction of propagation 102e may be a spatial average of the direction of movement of the solid particles in the coating region 803.

Generally, a main direction of propagation may denote a direction in which the emitted solid particles move on average (i.e. the gravitational center of the solid particles) over the course of time. The gravitational center of the solid particles (for example of the multitude of solid particles or a spatial distribution of solid particles) may be described as an average of the positions of the solid particles weighted by the mass of the solid particles. The main rate of propagation may denote a rate at which the solid particles move on average (i.e. the gravitational center of the solid particles). The average deviation from a main variable (main rate of propagation or main direction of propagation) may be understood as meaning a standard deviation about the main variable that is weighted by the mass of the solid particles. As an alternative or in addition to the main rate of propagation, a main impulse and/or a main kinetic energy of the solid particles and/or average deviation thereof may be used.

Optionally, the material vapor source 104 may comprise a plasma source for the plasma-assisted coating of the solid particles, for example by means of a plasma-assisted electron beam evaporation. The material vapor source 104 may then be configured for producing a plasma in the coating region 803.

FIG. 2B illustrates a processing arrangement 200b according to various embodiments in a schematic side view or cross-sectional view (for example in section along the two main directions of propagation 102e, 104e).

According to various embodiments, a collecting device 106 may be arranged in the collecting region 805. The collecting device 106 may comprise an opening 106o (may also be referred to as a collecting opening 106o) for collecting the solid particles. In other words, the collecting device 106 may be open in the direction of the coating region 803. For example, the collecting device 106 may comprise a collecting container 106b and/or a collecting funnel 106b, by means of which the opening 106o is provided. As an alternative or in addition, the collecting device 106 may comprise a transporting channel 106k, by means of which the opening 106o is provided. The collecting device 106 may be configured and aligned to collect at least part of the solid particles that enter the collecting region 805. The opening 106o may be directed toward the coating region 803.

The collecting container 106b and/or a collecting funnel 106b may optionally be coupled to a solid particle transporting device 402, which is configured to transport the solid particles collected in the collecting device 106 out of the vacuum chamber 802. As an alternative or in addition, the collecting container 106b may be cyclically emptied, for example outside the vacuum chamber 802 (for example in that it is in its entirety brought out of the vacuum chamber 802) or inside the vacuum chamber 802 (for example with the vacuum chamber 802 open).

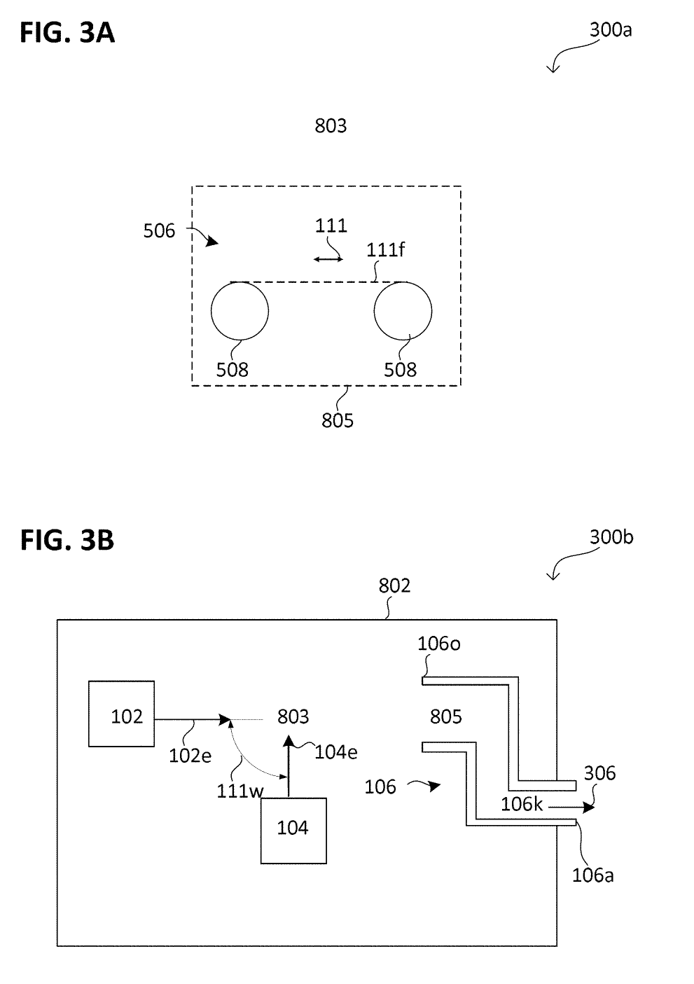

FIG. 3A illustrates a processing arrangement 300a according to various embodiments in a schematic side view or cross-sectional view (for example in section along a transporting direction 111).

According to various embodiments, a substrate transporting device 506 may be arranged in the collecting region 805. The substrate transporting device 506 may comprise multiple transporting rollers 508, which define a transporting area 111f, along which a substrate can be transported, for example along a transporting direction 111. According to various embodiments, the transporting area 111f and/or the substrate transporting device 506 may extend in the collecting region 805 and/or through the collecting region 805.

FIG. 3B illustrates a processing arrangement 300b according to various embodiments in a schematic side view or cross-sectional view (for example in section along the two main directions of propagation 102e, 104e).

According to various embodiments, the collecting device 106 may be configured for transporting the solid particles into a region outside the vacuum chamber 802. For example, the collecting device 106 may comprise a transporting channel 106k, through which the solid particles can be transported. The transporting channel 106k may comprise an opening 106o (entry opening, or channel entry 106o), which is arranged in the collecting region 805. The channel entry 106o may be directed toward the coating region 803.

The transporting channel 106k may extend through a chamber wall 802w of the vacuum chamber 802. The transporting channel 106k may comprise a further opening 106a (exit opening 106a or channel exit 106a) outside the vacuum chamber 802. Solid particles can leave 306 the vacuum chamber 802 through the transporting channel 106k.

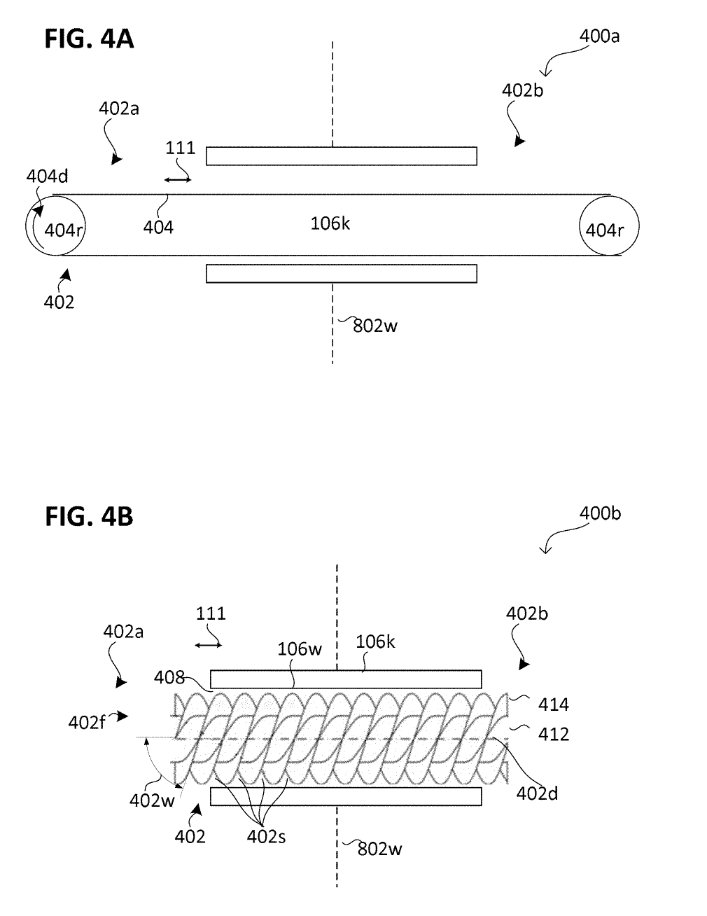

FIG. 4A illustrates a processing arrangement 400a according to various embodiments in a schematic side view or cross-sectional view (for example in section along a transporting direction 111).

According to various embodiments, the processing arrangement 400a may comprise a solid particle transporting device 402. The solid particle transporting device 402 may be configured to transport the solid particles in a transporting channel 106k and/or through the transporting channel 106k, for example along a transporting direction 111. The transporting channel 106k may for example extend through a chamber wall 802w of the vacuum chamber 802.

For example, the transporting channel 106k may extend between a first region 402a and a second region 402a. The first region 402a and the second region 402b may be spatially separated from one another by means of the chamber wall 802w. The first region 402a and the second region 402b may be connected to one another in a gas-separated manner through the transporting channel 106k.

For example, the first region 402a may be arranged inside the vacuum chamber 802 (for example if it is a vacuum region) and the second region 402b may be arranged outside the vacuum chamber 802 (for example if it is an atmospheric region), or as an alternative the other way around. Then, the first region 402a and the second region 402b differ in at least a pressure by more than one order of magnitude (for example more than approximately two, three, four, five, six, seven, eight, nine or for example more than approximately ten orders of magnitude). For example, the first region 402a may be at process pressure (for example a vacuum) and the second region 402b may be at atmospheric pressure (i.e. atmospheric air pressure). Optionally, the first region 402a and the second region 402b may define a chemical composition. For example, the first region 402a may have an atmospheric gas composition and the second region 402b may have a process gas composition (i.e. a chemical composition of the process gas).

As an alternative, the first region 402a and the second region 402b may be arranged inside the vacuum chamber 802 (for example in different vacuum chamber sections). Then, the first region 402a and the second region 402b can differ in at least a chemical composition. For example, the first region 402a may have a first process gas composition and the second region 402b may have a second process gas composition, which differs from the first process gas composition. Optionally, the first region 402a and the second region 402b may differ in a pressure by more than one order of magnitude (for example more than approximately 2, 3, 4, 5, 6, 7, 8, 9 or for example more than approximately 10 orders of magnitude).

The solid particle transporting device 402 may for example comprise a transporting belt 404, which is guided over multiple transporting belt rollers 404r. The transporting belt rollers 404r may be mounted rotatably 404d and/or be driven by means of a roller drive. The transporting belt 404 may comprise or be formed by a sheet, a nonwoven, a belt and/or a woven fabric.

For example, the first region 402a may be a collecting region 805 and the second region 402b may be an air-lock transfer region (i.e. a vacuum region that is supplied with air and evacuated in cycles). The solid particle transporting device 402 may be configured to extract the solid particles from the collecting region 805, for example while the solid particle source 102 is emitting solid particles, for example uninterruptedly.

As an alternative, the first region 402a may be an atmospheric region and the second region 402b may be a region of a solid particle source 102, inside its particle container. The solid particle transporting device 402 may be configured to supply the solid particle source 102 with solid particles (i.e. to feed the solid particles to the solid particle source 102) while the latter is emitting solid particles, for example uninterruptedly.

FIG. 4B illustrates a processing arrangement 400b according to various embodiments in a schematic side view or cross-sectional view (for example in section along the transporting direction 111).

According to various embodiments, the solid particle transporting device 402 may comprise a rotatably mounted conveying screw 402f. The conveying screw 402f may be arranged in the transporting channel 106k.

The conveying screw 402f may comprise a shaft 412 (may also be referred to as a screw shaft) and comprise at least one screw thread 414 (for example two or more intermeshing screw threads 414), which extends around the shaft 412.

According to various embodiments, the conveying screw 402f and the transporting channel 106k may be configured in relation to one another in such a way that a gas separation gap 408 is formed between the conveying screw 402f and the inner wall 106w of the transporting channel 106k (by way of illustration a small distance between the conveying screw 402f and the inner wall 106w of the transporting channel 106k).

The gas separation gap 408 may be understood as meaning a gap which makes an exchange of gas through the gas separation gap 408 more difficult. According to various embodiments, the gas separation gap 408 may have a gap height (i.e. a distance of the inner wall 106w and the conveying screw 402f) of less than 10 mm (for example a gap height of less than 9 mm, 8 mm, 7 mm, 6 mm, 5 mm, 4 mm, 3 mm, 2 mm or 1 mm) and/or of less than an extent of the solid particles. By way of illustration, the distance between the conveying screw 402f and the inner wall 106w of the transporting channel 106k can be as small as possible, while it is possible however for example for the running tolerances of the conveying screw 402f and the thermal expansions of the components involved to be taken into account.

The gas separation gap 408 may extend in the form of a tunnel along one direction (for example along the axis of rotation 402d of the conveying screw 402f), along which the gas separation is intended to take place. On account of the smallest possible opening width of the gas separation gap 408 and the great length of the gas separation gap 408 in comparison with the opening width of the transporting channel 106k, an effective gas separation can take place in a pressure range of less than approximately 1 mbar, for example with a pressure difference of more than one order of magnitude. An order of magnitude may refer to a ratio of two variables to one another (for example first pressure and second pressure) of approximately 10, i.e. a factor (or divisor) between the variables of approximately 10. Two orders of magnitude refers to a ratio of approximately 100 (10²), three orders of magnitude to a ratio of approximately 1000 (10³), and so on.

If, for example, at least one of the regions 402a, 402b comprises a vacuum, the gas separation gap 408 may be configured in such a way that a pressure ratio between the two regions 402a, 402b of more than 10 (for example more than approximately 10², 10³, 10⁴, 10⁵, 10⁶, 10⁷, 10⁸, 10⁹, or for example more than approximately 10¹⁰) can be maintained. In other words, the conveying screw 402f and the transporting channel 106k can bring about a vacuum separation.

By means of the gas separation gap 408, multiple pressure stages 402s may be provided, respectively separated from one another by means of a revolution of the screw thread 414. By way of illustration, the channel running in the form of a screw, which is delimited by the screw thread 414 and the inner wall 106w, may be filled with solid particles during the operation of the solid particle transporting device 402. On account of the fine grain size of the solid particles, they can provide an effective gas separation. In this way, the gas exchange is limited to a gas flow through the gas separation gap 408, so that each revolution of the screw thread 414 provides a pressure stage. The more revolutions the screw thread 414 has and/or the more screw threads 414 the conveying screw 402f has, the more pressure stages can be provided.

The geometry of the solid particle transporting device 402 and the operation thereof can be adapted to the requirements of the solid particle source 102. For example, the rotational speed, angle of inclination 402w (with respect to the axis of rotation 402d) of the screw thread 414 (which defines the number of screw revolutions per unit of length), the number of screw threads 414 per conveying screw 402f, the number of conveying screws 402f and/or the diameter thereof are increased in order to increase the amount of solid particles that are fed to the emission region 706 per unit of time (may also be referred to as the rate of supply).

For example, the rate of emission of the solid particles may be detected, and a rotational speed of the one or more conveying screws 402f adjusted and/or controlled on the basis of the rate of emission, for example by means of the control system. Consequently, for example, a continuous readjustmentation and consequently rate of emission can be achieved.

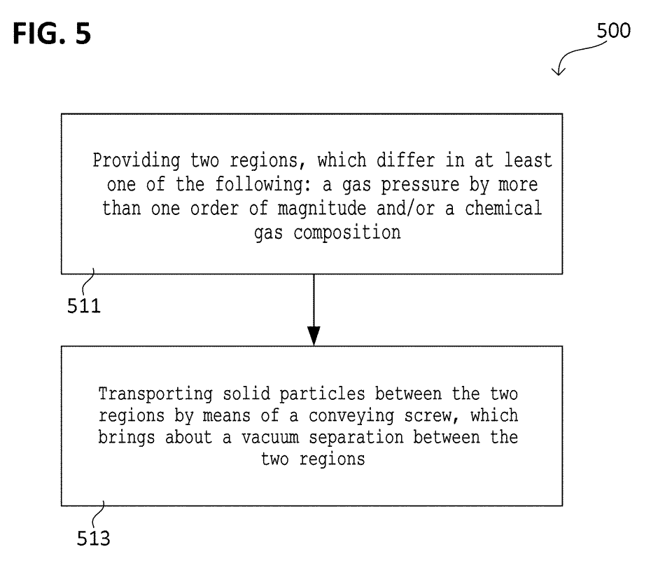

FIG. 5 illustrates a method 500 according to various embodiments in a schematic flow diagram.

According to various embodiments, the method 500 may comprise in 511: providing two regions, which differ in at least one of the following: a gas pressure by more than one order of magnitude (for example more than approximately two, three, four, five, six, seven, eight, nine or for example more than approximately ten orders of magnitude) and/or a chemical gas composition (for example in a gaseous constituent). Furthermore, the method 500 may comprise in 513: transporting solid particles between the two regions by means of a conveying screw, which brings about a vacuum separation between the two regions.

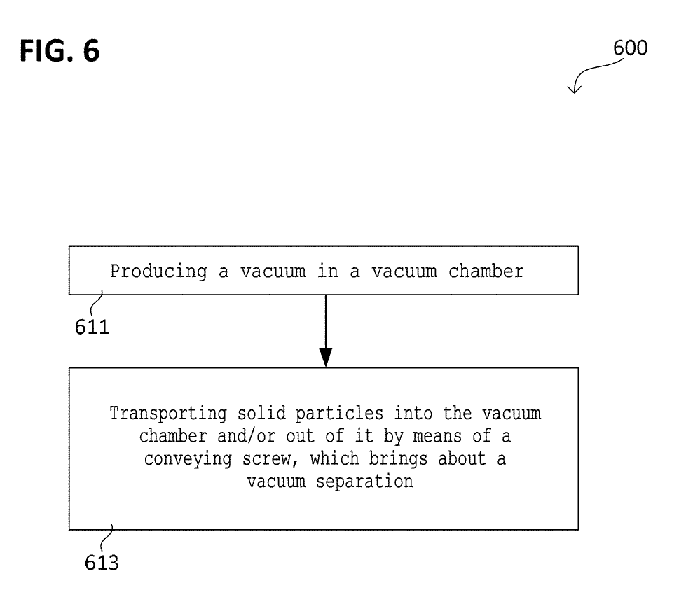

FIG. 6 illustrates a method 600 according to various embodiments in a schematic flow diagram.

According to various embodiments, the method 600 may comprise in 611: producing a vacuum in a vacuum chamber. Furthermore, the method 600 may comprise in 613: transporting solid particles into the vacuum chamber and/or out of it by means of a conveying screw, which brings about a vacuum separation.

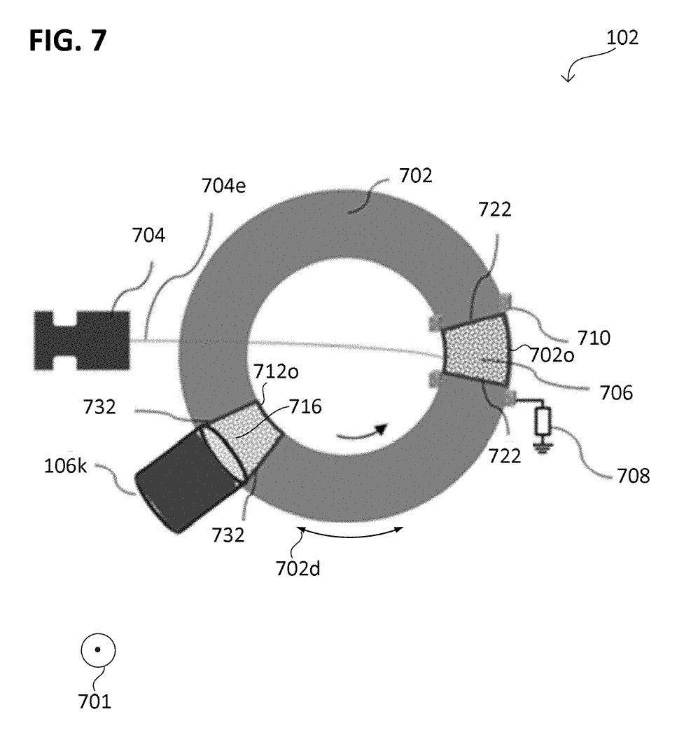

FIG. 7 a solid particle source 102 according to various embodiments in a schematic plan view or cross-sectional view (for example in section transversely in relation to a direction of emission 701).

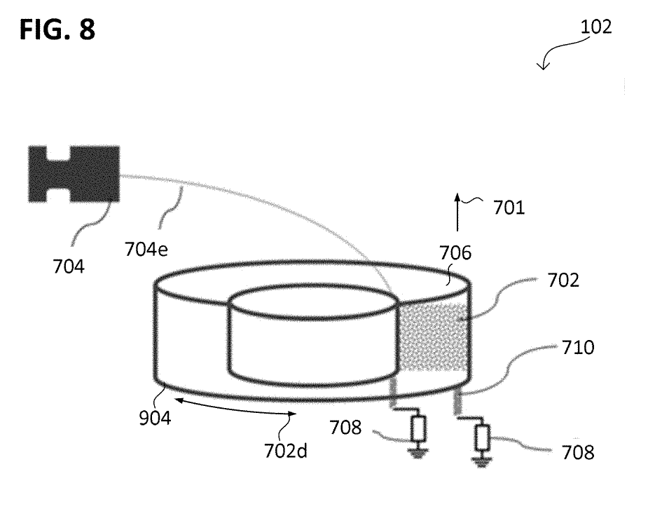

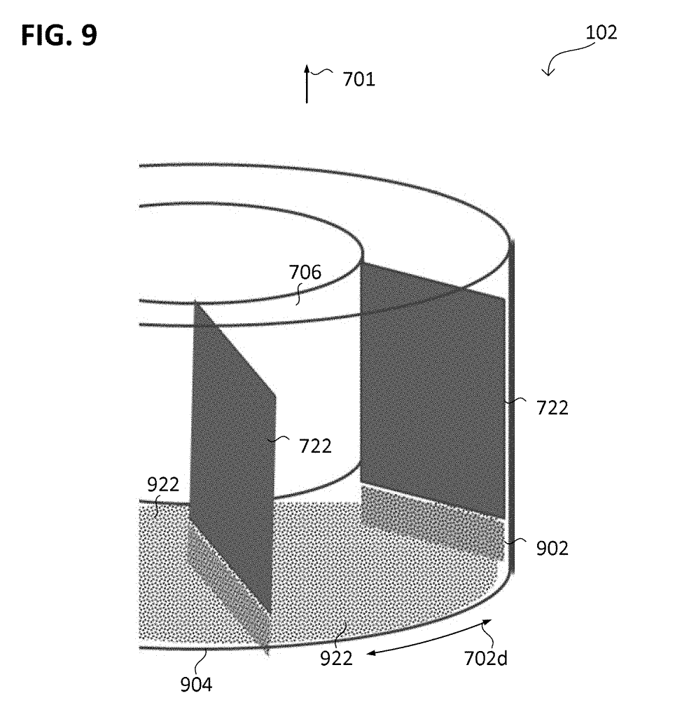

FIG. 8 illustrates the solid particle source 102 in a schematic perspective view and FIG. 9 in a schematic view of a detail.

According to various embodiments, the solid particle source 102 may comprise a particle container 702 (may also be referred to as a container 702 or crucible 702) for receiving the solid particles. The particle container 702 may for example comprise or be formed by graphite and/or metal. Optionally, the particle container 702 may be coolable by means of a temperature control device (not represented). The particle container 702 may be movably mounted.

In the with particle container 702, a stock of solid particles may be arranged. The solid particle source 102 may comprise an emission region 706. The particle container 702 may comprise a first opening 702o (may also be referred to as an emission opening 702o), which exposes and/or defines the emission region 706. The particle container 702 may comprise a second opening 712o (also referred to as a supply opening 712o), which exposes and/or defines a supply region 716.

The solid particle source 102 may comprise an electron beam source 704 (for example an electron beam gun 704). The electron-beam source 704 may be configured for producing an electron-beam 704e, by means of which the emission region 706 and/or the particle container 702 (for example the periphery of the emission opening 702o) can be irradiated. For example, the electron-beam source 704 may be configured to pass over the emission region 706 and/or the particle container 702 according to an irradiation figure. The irradiation figure may define a spatial distribution of the irradiation (for example energy and/or power density) and/or an irradiation time. For example, the irradiation figure may follow the outer contour of the emission region 706 (for example the periphery of the emission opening 702o) and/or extend in a meandering form in the emission region 706.

By means of the irradiation, electrons which can bring about an electrostatic charging of the solid particles can be transferred to the particle container 702 and/or the solid particles. The electrostatic charging of the solid particles may bring about a repelling force between them, which increases with increasing electrostatic charging. When a critical electrostatic charging is exceeded, the repelling force may bring about a (for example collective) separation and/or acceleration of part of the solid particles from the emission region 706, for example in that the surface layer of the solid particles is split off. In other words, the electrostatic charging of the solid particles by means of the electron bombardment, for example on the inner periphery of the crucible, can bring about the collective atomization. The accelerated solid particles may form a cloud of solid particles, which moves away from the emission region 706, for example in the direction of emission 701 (may for example run parallel to the first main direction of propagation 102e).

The particle container 702 may be grounded by means of an open-loop and/or closed-loop controllable electrical coupling 708 (for example an open-loop and/or closed-loop controllable resistor 708), so that for example part of the induced electrons can flow away. The resistor 708 may for example be electrically coupled to the particle container 702 by means of carbon brushes as sliding contacts 710. Optionally, the sliding contacts 710 may have a variable (for example an open-loop and/or closed-loop controllable) distance (for example along the direction of rotation 702d of the particle container 702) from the shields 722. In this way, a specific removal of the emitted electrons can be brought about. The variable (for example open-loop and/or closed-loop controllable) electrical coupling 708 to the particle container 702 brings about a controlled removal of the electrons (charges), whereby the extent of particle emission can be spatially controlled in an open-loop and/or closed-loop manner (for example the rate of solid particle emission and/or the timing of the emission).

In order to allow a high throughput (functionalization throughput) of the solid particles, according to various embodiments a continuous supply (replenishment) of the emission region 706 with solid particles can be provided, for example into the supply region 716 or through it.

Optionally, the particle container 702 (for example a grooved crucible) may comprise a rotatably 702d mounted base 904 (may also be referred to as a readjusting crucible). A supplying of the particle container 702 with the solid particles can take place into the supply opening 712o. While the particle container 702 is being supplied with solid particles, the particle container 702 or the base 904 can be turned, so that the solid particles fed in are transported to the emission region 706 by means of the rotation.

According to various embodiments, the particle container 702 may comprise two shields 722 (for example panels or grids) extending from the emission opening 702o into the interior of the particle container 702 (for example on opposite sides of the emission opening 702o). The shields 722 can provide continuous conditions in the emission region 706 on the basis of a controlled holding back of the solid particles from the peripheral regions. For example, the shields 722 can isolate the solid particles arranged in the emission opening 702o from the solid particles arranged in the supply opening 712o.

Optionally, the particle container 702 may comprise two further shields 732 (for example panels or grids) extending into the interior of the particle container 702 (for example arranged or opposite sides of the emission opening 702o). The further shields 732 can reduce and/or prevent an emission of the solid particles in out of the supply opening 712o.

The transporting channel 106k (for example a particle feeding channel and/or a particle removing channel) may comprise multiple pressure stages 402s. A continuous feed of solid particles (for example provided on the atmosphere side, i.e. provided in an atmospheric region) can take place through the transporting channel 106k. The feed may take place for example in an open-loop and/or closed-loop controlled manner, for example on the basis of a rate of emission (rate of solid particle emission). By way of illustration, the feed may take place in such a way that the amount of solid particles emitted is continuously replenished. In this way, a feed of a required amount of particles can be achieved in continuous operation of the solid particle source 102. Optionally, a conveying screw 402f may be arranged in the transporting channel 106k, as described above.

According to various embodiments, the particle container 702 may comprise a base plate 904, which is rotatably 702d mounted in relation to the openings 712o, 702o of the particle container 702. The openings 712o, 702o of the particle container 702 may be fixedly arranged. A gap 902 may be formed between the base plate 904 and the shields 722. By means of turning 702d the base plate 904, the solid particles 922 can be transported through the gap 902 into the emission region 706.

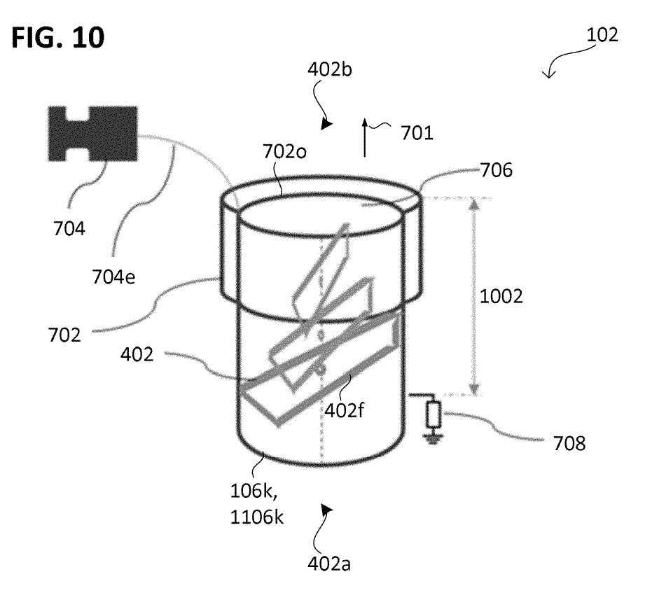

FIG. 10 illustrates a solid particle source 102 according to various embodiments in a schematic perspective view.

According to various embodiments, the transporting channel 106k may be a particle feeding channel 1106k, through which a supplying of the emission region 706 and/or the supply region 716 with solid particles takes place. For example, the transporting channel 106k may be configured to feed solid particles directly to the emission region 706.

As an alternative, the transporting channel 106k may be a particle removing channel 1116k (not represented, compare FIG. 11), through which the removal of (for example already coated) solid particles entering the collecting region takes place.

According to various embodiments, a conveying screw 402f may be arranged in the transporting channel 106k. The conveying screw 402f can provide multiple pressure stages 402s in the transporting channel 106k. In this way it can be achieved that the solid particles can be transferred out of the first region 402a (for example on the atmosphere side), which may be at a pressure greater than a vacuum (for example atmospheric pressure), continuously into a second region 402b (for example on the process side), which may be at a pressure equal to or less than a vacuum. In other words, a readjusting feed of solid particles can be provided by means of the conveying screw 402f (for example a worm screw), it being possible for the solid particles to be continuously transferred from an atmospheric pressure into a vacuum through multiple pressure stages 402s, or the other way around.

Optionally, the electron beam source 704 may be configured in such a way that the electron beam 704e impinges on the periphery of the particle container 702 (crucible). As a result, an electrical charging of the solid particles at the emission opening 702o can be brought about. The electrical charging may decrease in one direction (for example opposite to the direction of emission 701), for example by the open-loop and/or closed-loop controlled removal of the electrons.

For example, the electrical resistor 708 may contact the transporting channel 106k at a distance 1002 from the periphery of the particle container 702 and/or the emission region 706. As a result, a controlled removal of the electrically negative charges is brought about at the location of the contact. The controlled removal can a (for example explosive) repelling reaction of the solid particles, which are reduced or prevented by electrical charges accumulating in the interior of the transporting channel 106k. By way of illustration, an uncontrolled emission of solid particles can be suppressed.

FIG. 11 illustrates a processing arrangement 1100 according to various embodiments in a schematic perspective view.

The processing arrangement 1100 may comprise a coating region 803 and a collecting region 805.

The processing arrangement 1100 may comprise a solid particle source 102. The solid particle source 102 may be configured as described herein. The solid particle source 102 may emit solid particles 922 with a first main direction of propagation 102e through the coating region 803 into the collecting region 805. Optionally, the solid particle source 102 may comprise a guiding device 1102 for guiding (for example by means of deflecting) the emitted solid particles 922 into the first main direction of propagation 102e.

The guiding device 1102 may define a path 102p, along which the solid particles 922 move. The path 102p may run from the emission region of the solid particle source 102 to the collecting region 805. By way of illustration, the guiding device 1102 may form a guiding channel, along which the solid particles 922 can move. For example, the guiding device 1102 may bring about a mechanical deflection of the solid particles 922 (for example by mechanical impacts with the guiding device 1102). As an alternative or in addition, the guiding device 1102 may bring about an electrostatic and/or magnetic deflection of the solid particles 922. The magnetic deflection may for example take place on the basis of a residual charge of the emitted solid particles 922. For this purpose, the guiding device 1102 may comprise one or more magnets. The guiding device 1102 may for example define the first main direction of propagation 102e. The path 102p may run through the coating region 803 along the first main direction of propagation 102e.

The guiding device 1102 may for example comprise a first deflecting shield 1102a and a second deflecting shield 1102b, between which the path 102p runs.

As an alternative or in addition to the mechanical deflection, the guiding device 1102 may bring about an electrostatic deflection. Then, the guiding device 1102 may be coupled to a closed-loop and/or open-loop controlled voltage source 1104, which provides the guiding device 1102 with a deflecting potential. In this way, a closed-loop and/or open-loop controlled deflection of the solid particles 922 can be provided, for example on the basis of a spatial distribution of the solid particles 922 leaving the emission region of the solid particle source 102 and/or on the basis of a spatial distribution of the solid particles 922 entering the collecting region 805. For example, the voltage source 1104 may be controlled in an open-loop and/or closed-loop manner by means of the control system.

As an alternative or in addition, the guiding device 1102 may comprise one or more additional openings, whereby the primary electron beam impinges on the trajectory of the particle stream in an offset or directly quasi-perpendicular manner, in order to allow the conventional evaporation of the particles locally or along the direction of propagation of the particle stream.

The processing arrangement 1100 may also comprise a material vapor source 104. The material vapor source 104 may be configured and/or aligned to emit a gaseous coating material with a second main direction of propagation 104e into the coating region 803. In other words, the material vapor source 104 may be configured to produce a material vapor stream 104d in the direction (second main direction of propagation 104e) of the coating region 803. The material vapor source 104 may comprise a further electron beam source 1704 (for example of an electron beam gun 1704), by means of which the coating material can be evaporated.

A collecting device 106, which may be similar or identical to one of the solid particle sources described herein (and for example be operated in a backward mode) may be arranged in the collecting region 805.

The collecting device 106 may comprise a collecting opening 106o, which collects at least part of the solid particles 932 that enter the collecting region 805. The collected solid particles 932 may be fed to the solid particle transporting device 402. The solid particle transporting device 402 may be configured to transport the solid particles 932 out of the vacuum chamber 802. The solid particles 932 entering the collecting region 805 may be at least partially coated (may also be referred to as coated solid particles 932).

The first main direction of propagation 102e and the second main direction of propagation 104e may extend at an angle to one another in such a way that the material vapor stream 104d is directed past the collecting region 805. Consequently, it can be prevented that the collecting region 805 and/or the collecting device 106 are coated with the coating material. The coating material may comprise or be formed by an active material.

Optionally, the guiding device 1102 may at least partially surround the coating region 803. Then, the guiding device 1102 may for example comprise an opening 1102o, which exposes the coating region 803 with respect to the material vapor source 104.

The coating region 803 may have an extent 803d (may also be referred to as the coating zone 803d) along the first main direction of propagation 102e, which are defined by a propagation characteristic of the material vapor stream 104d (i.e. a propagation characteristic of the evaporated coating material) and/or of the opening 1102o.

The propagation characteristic may comprise at least one of the following: the second main direction of propagation 104e, an average deviation from the second main direction of propagation 104e (for example a dihedral angle into which the material vapor stream 104d propagates), a main rate of propagation, or an average deviation from the main rate of propagation.

During the operation of the processing arrangement 1100, an electron beam 704e may be directed onto the particle container 702, for example the periphery thereof, for example by means of an electron beam source 704 (may also be referred to as the radiation source). Solid particles 922 (may also be referred to as atomization material or solid particle material) may be arranged in the particle container 702. On account of a static charging of the solid particles 922, a (for example collective) emission of the solid particles 922 can be brought about. The particle container 702 may optionally be configured for replenishing the emitted solid particles 922, for example by analogy with the particle container 702 illustrated in FIG. 7 to FIG. 9 (for example a readjusting crucible).

The particle container 702 may be configured in such a way that (for example a large part of) the solid particles 922 loaded (for example to the full extent) into the guiding device 1102 (by way of illustration a structure located above it). The guiding device 1102 or its guiding channel may bring about a (for example specific, for example closed-loop and/or open-loop controlled) guidance (by way of illustration a deflection) of the solid particles 922, for example by means of scattering, electrostatic repulsion and/or reflection.

In order to keep the second deflecting shield 1102b free of solid particles 922, a negative potential (deflecting potential) may be applied to it. As an alternative or in addition, the guiding device 1102 may comprise an inner guiding structure, for example an array (grid or raster) of multiple smaller channels (may also be referred to as a collimator), i.e. a collimator guiding structure.

Optionally, a cross-sectional area (for example transverse to the path 102p) of the guiding channel may become smaller along the path 102p (for example in the first main direction of propagation 102e) (may also be referred to as tapering), for example by means of a length-dependent reduction in diameter. The diminishing cross-sectional area may in this case bring about an interaction that increases in the main direction of propagation 102e (for example impacts and/or electrostatic repulsion) of the solid particles 922 with one another and/or with the guiding device 1102 (for example with its channel walls). The interaction may increase a velocity of the solid particles 922, which can improve the coating (for example functionalization).

For example, a repulsion potential may be provided for the solid particles 922 (for example comprising or formed by graphite) in such a way that, with respect to a reference potential (for example electrical ground), a potential difference in a range from approximately −300 volts (V) to approximately −700 V can be provided. For example, the solid particles 922 may have an average diameter of approximately 17 μm.

In dependence on the performance parameters of the electron beam source 704, many electrons can be introduced into the solid particles 922 (for example comprising or formed by graphite) in such a way that they move along the path 102p with a main rate of propagation in a range from approximately 1 meter per second (m/s) to approximately 4 m/s, for example within the coating region 803.

On the basis of the coating zone 803d and/or the main rate of propagation, a rate of evaporation (i.e. evaporated coating material per unit of time) of the material vapor source 104 and/or the main rate of propagation can be controlled in an open-loop and/or closed-loop manner. The rate of evaporation of the material vapor source 104 may lie in a range from approximately 1 nanometer and meter per second (nm·m/s) to approximately 50 nm·m/s, for example in a range from approximately 2 nm·m/s to approximately 10 nm·m/s, for example approximately 6 nm·m/s.

The rate of evaporation and/or the main rate of propagation may as an alternative or in addition take place on the basis of a predetermined thickness of the coating material (layer thickness) that is to be deposited onto the solid particles 922, i.e. the thickness of the layer formed on the solid particles 922.

According to various embodiments, a spherically averaged layer thickness may lie in a range from approximately 0.1 nm to approximately 50 nm, for example in a range from approximately 0.2 nm to approximately 10 nm, for example in a range from approximately 0.4 nm to approximately 1.4 nm. By way of illustration, the layer may comprise or be formed by a functional layer. Functional layers of this thickness may be sufficient to change the chemical and physical properties of the solid particles 922. For example, the coating material may comprise or be formed by aluminum oxide (Al₂O₃).

The coated solid particles 932 (for example superficially modified solid particles 922) may subsequently be gathered in the collecting region 805 by means of a collecting container 106b and/or a collecting funnel 106b and optionally brought out (removed) from the vacuum chamber 802.

FIG. 12 illustrates a processing arrangement 1200 according to various embodiments in a schematic perspective view.

According to various embodiments, the material vapor source 104 may comprise multiple vapor sources 104t, for example multiple evaporation crucibles and/or multiple rod evaporators, in which the coating material is arranged. As an alternative or in addition, the material vapor source 104 may be configured to emit multiple material vapor streams into the coating region 803.

The guiding device 1102 of the solid particle source 102 may have an output 1102e (may also be referred to as an emission output 1102e). The output 1102e may comprise one or more openings, which define(s) a propagation characteristic of the solid particles 922 entering the coating region 803. For example, the guiding device 1102 may be configured in such a way that the propagation characteristic of the solid particles 922 that enter the coating region 803 is flat and/or fan-shaped. In this way, coating of the solid particles 922 can take place more uniformly.

For example, the guiding device 1102 may comprise a collimator structure 1102e, which is configured to bring about an anisotropic propagation characteristic of the solid particles 922. For example, the solid particle stream 922s (for example with a flat propagation characteristic) in the coating region 803 may have an extent in the second main direction of propagation 104e that is less than transverse to the first main direction of propagation 102e and the second main direction of propagation 104e. By way of illustration, a particle jet may be provided.

The collecting device 106 may comprise a further guiding device 1202. The further guiding device 1202 may comprise the collecting opening 106o. The further guiding device 1202 can guide the solid particles 922 entering the collecting region 805 to the collecting container 106b and/or the collecting funnel. As an alternative or in addition, the further guiding device 1202 can guide the solid particles 922 entering the collecting region 805 to a solid particle transporting device 402.

The guiding device 1102 and/or the further guiding device 1202 may extend in a curved and/or angled manner. For example, each of these may comprise a first opening, which is directed in the direction of gravitational force, and/or each may comprise a second opening, which are directed toward one another and/or toward the coating region 803.

By way of illustration, the emitted solid particles 922 may be loaded into a deflecting tube 1102r of the guiding device 1102. Optionally, the deflecting tube 1102r may be biased at a negative potential (deflecting potential), whereby for example effective conductance and/or guidance and respective unloading of the solid particles 922 out of the guiding device 1102 (for example through the collimator structure) can be achieved. For example, the individual channels of the collimator structure may open out in a gap (by way of illustration a slit) or have a round cross section (for example an array of channels), for example be formed with an aspect ratio of greater than 1, for example greater than 10. The aspect ratio can describe the ratio of two extents perpendicular to one another (by way of illustration more long than thin and/or wide).

According to various embodiments, for example in dependence on the coating material and/or the rate of evaporation, multiple vapor sources 104t may be provided, for example more than two, three, four, five, six, seven, eight, nine, or for example more than ten. The multiple vapor sources 104t may be arranged one behind the other along the first main direction of propagation 102e (for example in a line).

The electron beam source 1704 of the material vapor source 104 may be configured for irradiating each vapor source 104t of the multiple vapor sources 104t. For example, the electron beam source 1704 may be controlled in an open-loop and/or closed-loop manner according to multiple sets of deflecting parameters, for example by means of the control system. Each set of deflecting parameters of the multiple sets of deflecting parameters may be assigned to precisely one vapor source 104t and/or define an irradiation figure which brings about an irradiation in each case of one vapor source 104t of the multiple vapor sources 104t (for example of the assigned vapor source 104t).

The transporting belt 404 may according to various embodiments transport the collected solid particles 922 with a directional component along the direction of gravitation. In other words, the transporting belt 404 (or the surface on which the solid particles attach themselves) may be arranged obliquely or vertically. As an alternative, instead of the transporting belt 404, a fixed two-dimensional element (for example a wall, a sheet, or the like) may be used.

FIG. 13 illustrates a processing arrangement 1300 according to various embodiments in a schematic perspective view, for example similar to the processing arrangement 1200 illustrated in FIG. 12.

According to various embodiments, the multiple vapor sources 104t (for example in each case in pairs and/or in each case adjacent to one another) may be arranged obliquely in relation to one another. For example, the multiple vapor sources 104t may differ in their direction of emission 1302e.

According to various embodiments, the multiple vapor sources 104t may be arranged at a defined distance and angle 1302 in relation to one another, for example along a space curve (for example a circular path). For example, more than two directions of emission 1302e may be directed at a common point.

For the specific removal of the solid particles 922, they may after coating be collected by a, for example conical, opening 106o, of the collecting device 106 (for example its guiding device 1202) (i.e. enter the opening 106o).

Optionally, there may be a negative potential (for example the deflecting potential) at the collecting device 106, or its guiding device 1202. By means of the collecting device 106, the solid particles 922 can be guided in the direction of the collecting container 106b, the collecting funnel 106b and/or the solid particle transporting device 402.

FIG. 14 illustrates a processing arrangement 1300 according to various embodiments in a schematic perspective view, for example similar to the processing arrangement 1200 illustrated in FIG. 12.

According to various embodiments, the collecting device 106 (or its solid particle transporting device 402) may comprise a transporting belt 404 (for example a sheet, a woven fabric and/or a metal strip), which (for example over a corresponding width) is rotatably 404d mounted, for example by means of transporting belt rollers 404r. The transporting belt 404 may be moved by means of rotating the transporting belt rollers 404r. For example, the transporting belt 404 (for example transporting) may be arranged and/or held continuously in the corridor of the solid particle stream 922s.

The solid particles 922 from the solid particle stream 922s may attach themselves on the transporting belt 404 (i.e. its surface) (i.e. they are adsorbed). The attached solid particles 922 can be transported by means of the transporting belt 404 in the direction of the collecting container 106b and/or the transporting channel 106k. As an alternative or in addition to the collecting container 106b, the solid particles 922 may be received by a transporting channel 106k, in which a conveying screw 402f is arranged.

For example, the solid particles 922 may be separated from the transporting belt 404 by means of a stripping mechanism (for example controlled in a closed-loop and/or open-loop manner). By way of illustration, the stripping mechanism may provide an active separation of the solid particles 922 from the transporting belt 404. The separated solid particles 922 can then fall into the collecting container 106b or transporting channel 106k lying thereunder (for example along the gravitational force).

As an alternative or in addition, the separation of the solid particles 922 from the transporting belt 404 may result from a state of equilibrium (steady state) (for example automatically), for example from when the transporting belt 404 is filled up to a certain extent with solid particles 922. The automatic separation may take place for example in the part of the transporting belt 404 that runs in a curved manner at the transporting belt roller 404r.

As an alternative or in addition, a plasma-assisted coating may be performed in the coating described herein of the solid particles 922. For example, the material vapor source 104 may comprise a plasma source. In other words, a plasma-assisted electron beam evaporation (SAD) may take place.

According to various embodiments, the material vapor source 104 and solid particle source 102 described herein may comprise a common electron beam source 704 (for example electron beam gun 704). By way of illustration, a (for example small) fraction of the electron beam power may be required for the (for example collective) emission of solid particles 922 by means of an electron beam 704e. As a result, it is possible to bring about an evaporation of the coating material by means of the remaining electron beam power. For example, the processing arrangement may comprise precisely one electron beam source 704 (for example electron beam gun 704). For example, the electron beam 704e may be deflected in an open-loop and/or closed-loop controlled manner by means of multiple sets of deflecting parameters, for example by means of the control system. A first set of deflecting parameters of the multiple sets of deflecting parameters may be assigned to the material vapor source 104 and/or define an irradiation figure which brings about an irradiation of the one material vapor source 104. A second set of deflecting parameters of the multiple sets of deflecting parameters may be assigned to the solid particle source 102 and/or define an irradiation figure which brings about an irradiation of the one solid particle source 102.

According to various embodiments, a direction (direction of emission 701) with which solid particles 922 are emitted may extend horizontally (transversely in relation to the direction of gravitational force), for example in a PVD installation (PVD—physical vapor-phase deposition). In that case it is possible for example to dispense with the deflection of the path 102p, for example by means of a guiding device 1102.

According to various embodiments, a positive potential with respect to a reference potential (for example electrical ground) may be applied to the collecting device 106 (for example its collecting container 106b, transporting channel 106k and/or a collecting funnel 106b).

According to various embodiments, the guiding device 1102 and/or the further guiding device 1202 may comprise multiple segments (for example rings) through which the path 102p runs. The segments may differ for example in an electrical potential. For example, the electrical potential may bring about a reduction in the velocity of the solid particles 922 along the path (for example along the first main direction of propagation 102e). Such a guiding device 1102, 1202 may for example be arranged on the collecting container 106b (may also be referred to as a collecting/gathering crucible) and/or on the particle container 702 (may also be referred to as an unloading/emitting crucible).

FIG. 15A, FIG. 15B and FIG. 16 respectively illustrate a processing arrangement 1500a, 1500b, 1600 according to various embodiments in a schematic cross-sectional view or side view (for example in section transversely in relation to a main direction of propagation 102e, 104e).

According to various embodiments, a processing arrangement 1500a, 1500b, 1600 may comprise at least one processing chamber 802 (one or more processing chambers 802). Furthermore, the processing arrangement 1500a, 1500b may comprise a coating device 102, 104 according to various embodiments, which comprises a solid particle source 102 and a material vapor source 104. The material vapor source 104 may be configured for emitting at least one coating material in the direction 104e of the coating region 803. The solid particle source 102 may be configured for emitting solid particles in the direction 102e of the coating region 803.

Furthermore, the processing arrangement 1500a, 1500b may comprise a substrate transporting device 506 for transporting a substrate 504 along a transporting area 111f through the collecting region 805 and/or into the at least one processing chamber 802, as illustrated in FIG. 15A and FIG. 15B. As an alternative, the processing arrangement 1600 may comprise a collecting device 106 in the collecting region 805, as illustrated in FIG. 16.

The at least one processing chamber 802 (one or more processing chambers 802) may be provided by means of the chamber housing. The at least one processing chamber 802 may be configured to produce and/or maintain a vacuum therein. For example, the processing arrangement 1500a, 1500b, 1600 may comprise multiple processing chambers 802, of which for example two processing chambers 802 that are adjacent to one another adjoin one another. The adjoining processing chambers 802 may be connected to one another by means of a substrate transfer opening, so that they form for example a common vacuum system. As an alternative or in addition, some other chamber, for example a gas separation chamber, may be arranged between two processing chambers 802.

According to various embodiments, the processing arrangement 1500a, 1500b, 1600 may comprise a pump arrangement 814 (comprising at least one high-vacuum pump). The pump arrangement 814 may be configured to extract a gas (for example the process gas) from at least one processing chamber 802 (for example the vacuum chamber 802) or a vacuum region 1502 (for example in the interior of the vacuum chamber 802), so that within the at least one processing chamber 802 or the vacuum region 1502 a pressure of less than 0.3 bar (in other words a vacuum), for example a pressure in a range from approximately 10⁻³ millibars (mbar) to approximately 10⁻⁷ mbar (in other words a high vacuum) or a pressure of less than a high vacuum, for example less than approximately 10⁻⁷ mbar (in other words an ultrahigh vacuum), can be provided.

Furthermore, the at least one processing chamber 802 may be configured in such a way that a vacuum characteristic (the process characteristic) within the at least one processing chamber 802 (for example process pressure, process temperature, chemical composition of the process gas, etc.) can be adjusted or controlled, for example during the coating of the solid particles or solid particle emission, for example by means of the control system 518 (for example according to predetermined desired vacuum conditions).

According to various embodiments, the processing arrangement 1500a, 1500b, 1600 may comprise a gas supply 1702. By means of the gas supply 1702, the at least one processing chamber 802 can be fed a process gas for forming a process atmosphere in the at least one processing chamber 802. The process gas may for example comprise or be formed by a working gas and/or a reactive gas. The process pressure may be formed by an equilibrium of process gas that is fed in by means of the gas supply 1702 and extracted by means of the pump arrangement 814.

According to various embodiments, the reactive gas may comprise at least one of the following: oxygen, nitrogen, hydrogen sulfide, methane, gaseous hydrocarbons, fluorine, chlorine, one or other gaseous material. As an alternative or in addition, the working gas may comprise or be formed by an inert gas, such as for example a noble gas, for example argon. The reactive gas may have a higher chemical reactivity than the working gas, for example with respect to the coating material.

According to various embodiments, the processing arrangement 1500a, 1500b, 1600 may comprise a control system 518, which may be coupled to one or more component parts of the processing arrangement 1500a, 1500b, 1600 (shown by dashed lines) for controlling them in an open-loop and/or closed-loop manner, for example to the solid particle source 102, to the material vapor source 104, to the collecting device 106 or substrate transporting device, to the solid particle transporting device 402, to the pump arrangement 814 and/or to the gas supply 1702.

According to various embodiments, the control system 518 may be configured for controlling the vacuum conditions in an open-loop and/or closed-loop manner. For example, the gas supply 1702 and/or the pump arrangement 814 may be controlled in an open-loop and/or closed-loop manner by means of the control system 518, for example on the basis of a stipulation (for example desired vacuum conditions). The stipulation may for example comprise a chemical composition of the gas in the interior of the processing chamber 802.

According to various embodiments, the control system 518 may be configured for controlling the solid particle source 102 in an open-loop and/or closed-loop manner, for example on the basis of a stipulation (for example a desired operating parameter characteristic). The stipulation may for example represent an operating parameter of the solid particle source 102 (for example electrical power consumed, electrical voltage applied, rate of emission of the solid particles). As an alternative or in addition, the control system 518 may be configured for controlling the material vapor source 104 in an open-loop and/or closed-loop manner, for example on the basis of a stipulation (for example a desired operating parameter characteristic). The stipulation may for example represent an operating parameter of the material vapor source 104 (for example electrical power consumed, electrical voltage applied, rate of emission of the coating material).

For example, an actual operating parameter characteristic may be controlled in an open-loop and/or closed-loop manner by means of the control system 518, for example by means of adjusting or controlling operating parameters, for example on the basis of the desired operating parameter characteristic. As an alternative or in addition, the coating of the solid particles may take place in an open-loop and/or closed-loop controlled manner. Then, the stipulation may represent a coating characteristic (a desired coating characteristic). The coating characteristic may comprise at least one of the following: a layer thickness (for example spatially averaged and/or the spatial distribution thereof), a chemical composition of the layer (for example spatially averaged and/or the spatial distribution thereof) and/or a coating rate. The chemical composition of the layer may for example be defined by the reaction stoichiometry.

According to various embodiments, the processing arrangement 1500a may comprise a substrate transporting device 506 for transporting a substrate 504 through the collecting region 805. The substrate may be coated with the solid particles in the collecting region 805.

According to various embodiments, the transporting device 506 of the processing arrangement 1500a may comprise an unwinding roller 1002a for unwinding a strip-shaped substrate 504 into the coating region 803. Furthermore, the transporting device 506 of the processing arrangement 1500a may comprise a winding-up roller 1002b for winding up the strip-shaped substrate 504 which is brought out from the coating region 803. A strip-shaped substrate 504 (strip substrate) may comprise or be formed by a sheet, a nonwoven, a strip and/or a woven fabric. For example, a strip-shaped substrate 504 may comprise or be formed by a metal strip, a metal sheet, a plastic strip (polymer strip) and/or a plastic sheet (polymer sheet). The substrate transporting device 506 of the processing arrangement 1500a may comprise a multiplicity of transporting rollers 508, which define a (for example singly or multiply curved) transporting path 111f (or a correspondingly singly or multiply curved transporting area 111f), along which the strip-shaped substrate 504 is transported between the unwinding roller 1002a and the winding-up roller 1002b through the coating region 803. As an alternative, the strip-shaped substrate 504 may also be used as a transporting belt 404, for transporting solid particles out of the vacuum chamber. The transporting belt 404 may comprise or be formed by a sheet, a nonwoven, a strip and/or a woven fabric.

As an alternative to this, the transporting device 506 of the processing arrangement 1500b may comprise a multiplicity of transporting rollers 508, which are configured for transporting a plate-shaped substrate 504. The plate-shaped substrate 504 may be transported for example lying on the transporting rollers 508 and/or placed into a substrate carrier 1110. As an alternative, the substrate 504 may be transported lying on a transporting belt 404.

The substrate 504 may be coated with the coated solid particles by means of the processing arrangement 1500a, 1500b in the collecting region 805. In other words, the coated solid particles may be collected by means of the substrate 504. According to various embodiments, the material vapor source 104 may also be omitted, for example if the substrate 504 is only to be coated with the solid particles.

As an alternative to this, the processing arrangement 1600 may comprise a collecting device 106, which is configured for collecting the coated solid particles. The plate-shaped substrate 504 may be transported for example lying on the transporting rollers 508 and/or placed into a substrate carrier 1110. For example, the processing arrangement 1600 may comprise at least one solid particle transporting device 402. For example, a solid particle transporting device 402 of the solid particle source 102 and a solid particle transporting device 402 of the collecting device 106 may provide a transport 1604 of solid particles 922 through the vacuum chamber 802. During the transport of the solid particles 922 through the vacuum chamber 802, the solid particles may be coated with the coating material. According to various embodiments, more than approximately 50 kg of solid particles per hour (50 kg/h) may be transported into the vacuum chamber 802 and/or out of it (for example through it) (transporting rate) and/or be coated in the vacuum chamber 802 (coating rate), for example more than approximately 100 kg/h, for example more than approximately 150 kg/h, for example more than approximately 200 kg/h, for example more than approximately 300 kg/h, for example more than approximately 500 kg/h, for example more than approximately 500 kg/h. Outside the vacuum chamber 802, an atmospheric region may be arranged, or at least a pressure greater than a vacuum may prevail.

Furthermore, the processing arrangement 1500a, 1500b may comprise a drive 1602, which is coupled to at least one of the transporting devices 402, 506 (solid particle transporting device 402 and/or substrate transporting device 506), for example to the rollers 508, 1002a, 1002b and/or to the conveying screw 402f. For example, the drive 1602 may be coupled to at least one of the transporting devices 402, 506 by means of chains, belts or gearwheels.

According to various embodiments, the control system 518 may be configured for controlling the drive 1602 in an open-loop and/or closed-loop manner. For example, a transporting state (for example a transporting speed, a transporting position, a through-flow, etc.) may be controlled in an open-loop and/or closed-loop manner by means of the control system 518, for example on the basis of a stipulation which represents for example a desired coating characteristic and/or a desired transporting state.

At least one of the solid particle transporting devices 402 may comprise a conveying screw 402f.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims, and all changes which come within the meaning and range of equivalency of the claims are therefore

1. A method, comprising:
producing a vacuum in a coating region and in a collecting region;
emitting solid particles with a first main direction of propagation through the coating region into the collecting region;
evaporating a coating material with a second main direction of propagation into the coating region, the first main direction of propagation and the second main direction of propagation extending at an angle to one another in such a way that the coating material is evaporated past the collecting region.

2. The method as claimed in claim 1, further comprising:
collecting the solid particles in the collecting region after they have crossed through the coating region, by means of a collecting device and/or by means of a substrate.

3. The method as claimed in claim 1, further comprising:
transporting the solid particles between the collecting region and a region having a pressure greater than vacuum during the emission of the solid particles.

4. The method as claimed in claim 1, further comprising:
transporting the solid particles between an emission region and a region having a pressure greater than a vacuum during the emission of the solid particles from the emission region with the first main direction of propagation through the coating region into the collecting region.

5. The method as claimed in claim 1,
the solid particles in the coating region being coated with the coating material.

6. The method as claimed in claim 1,
the emission of the solid particles and/or the evaporation of the coating material are conducted through precisely one electron beam source or by means of multiple electron beam sources.

7. A processing arrangement, comprising:
a vacuum chamber with a coating region and a collecting region;
a solid particle source, which is configured to emit solid particles with a first main direction of propagation through the coating region into the collecting region;
a material vapor source, which is configured to evaporate a coating material with a second main direction of propagation into the coating region;
the first main direction of propagation and the second main direction of propagation extending at an angle to one another in such a way that the material vapor source evaporates the coating material past the collecting region.

8. The processing arrangement as claimed in claim 7, further comprising:
a collecting device and/or a substrate transporting device, which extend in the collecting region.

9. The processing arrangement as claimed in claim 8,
the collecting device being configured for transporting the solid particles into a region outside the vacuum chamber.

10. The processing arrangement as claimed in claim 7, the solid particle source being configured for transporting the solid particles that are to be emitted into the coating region out of a region outside the vacuum chamber.

11. The processing arrangement as claimed in claim 7,
the solid particle source and the material vapor source comprising:
a single common electron beam source; or
each of the solid particle source and the material vapor source comprising at least one electron beam source.

12. A method, comprising:
producing a vacuum in a vacuum chamber; and
transporting solid particles into the vacuum chamber and/or out of it by means of a conveying screw, which brings about a vacuum separation.

13. (canceled)

14. (canceled)

15. (canceled)
